(19) United States
(12) Patent Application Publication
(10) Pub. No.: US 2024/0055456 A1
(43) Pub. Date: Feb. 15, 2024

(54) SOLID-STATE IMAGING DEVICE

(71) Applicant: SONY SEMICONDUCTOR SOLUTIONS CORPORATION, Kanagawa (JP)

(72) Inventors: Shinichiro NOUDO, Kanagawa (JP); Tomohiro YAMAZAKI, Kanagawa (JP); Yoshiki EBIKO, Kanagawa (JP); Sozo YOKOGAWA, Kanagawa (JP); Tomoharu OGITA, Kanagawa (JP); Hiroyasu MATSUGAI, Kanagawa (JP); Yusuke MORIYA, Kanagawa (JP)

(73) Assignee: SONY SEMICONDUCTOR SOLUTIONS CORPORATION, Kanagawa (JP)

(21) Appl. No.: 18/260,491

(22) PCT Filed: Aug. 13, 2021
(86) PCT No.: PCT/JP2021/029828

§ 371 Date: Jul. 6, 2023

(30) Foreign Application Priority Data
Jan. 13, 2021 (JP) 2021-003801

(51) Int. Cl. H01L 27/146

(52) U.S. Cl. CPC H01L 27/14627; H01L 27/1463; H01L 27/14629; H01L 27/14623

(57) ABSTRACT

A solid-state imaging device according to an embodiment includes: a plurality of pixels, each of the plurality of pixels including a substrate having a first surface serving as a light incident surface, a photoelectric conversion unit located inside the substrate, a light shielding unit provided on a first surface side, the light shielding unit having a hole portion configured to allow light to be incident on the photoelectric conversion unit, and a first lens made of silicon, the first lens being provided on the light shielding unit and condensing incident light toward the hole portion.

### FIELD

The present disclosure relates to a solid-state imaging device.

### BACKGROUND

In recent years, there is an increasing demand for a light receiving element capable of sensing light having a wavelength longer than that of visible red light and a wavelength shorter than that of light in a far infrared region (hereinafter, referred to as infrared light) among light having wavelengths in an infrared region. For example, a portable electronic device such as a smartphone may perform user authentication or the like based on an image including infrared light or a distance measurement result using infrared light.

While a light receiving element such as a photodiode using a silicon (Si) layer as a light absorbing layer has sensitivity to infrared light, a light absorbing coefficient per unit thickness decreases as a wavelength becomes longer due to wavelength dependency of the light absorbing coefficient of Si, and as such, most of photons of long-wavelength light incident on the Si layer pass through the Si layer.

As a method of obtaining high sensitivity to light on the long wavelength side in the light receiving element, various methods have been proposed. For example, Patent Literature 1 proposes a structure in which a reflection structure is provided on a surface on the opposite side of a light receiving surface, a pinhole is provided between an on-chip lens and a substrate (Si layer), and reflected light by the surface on the opposite side of the light receiving surface is confined in the Si layer. With the structure proposed in Patent Literature 1, the light confined in the Si layer is reflected by the reflection structure, so that an optical path length is increased, photoelectric conversion can be more efficiently performed, and high sensitivity can be expected.

### CITATION LIST

### Patent Literature

Patent Literature 1: JP 2019-114642 A
Patent Literature 2: JP 2008-147333 A
Patent Literature 3: WO 2020/012984 A
Patent Literature 4: JP 2019-180048 A

### SUMMARY

### Technical Problem

However, in the related art, light is not sufficiently narrowed in an on-chip lens with respect to light emitted to a light receiving element, and a loss of light in a pinhole structure portion is large.

An object of the present disclosure is to provide a solid-state imaging device capable of achieving higher sensitivity.

### Solution to Problem

For solving the problem described above, a solid-state imaging device according to one aspect of the present disclosure has a substrate having a first surface serving as a light incident surface; a photoelectric conversion unit located inside the substrate; a light shielding unit provided on a side of the first surface, the light shielding unit having a hole portion configured to allow light to be incident on the photoelectric conversion unit; and a first lens made of silicon, the first lens being provided on the light shielding unit and condensing incident light toward the hole portion.

### BRIEF DESCRIPTION OF DRAWINGS

FIG. 1 is a block diagram illustrating a configuration of an example of an electronic device applicable to a first embodiment of the present disclosure.

FIG. 2 is a block diagram illustrating a configuration of an example of an imaging unit applicable to the first embodiment.

FIG. 3 is a circuit diagram illustrating a circuit of an example of a pixel applicable to the first embodiment.

FIG. 4 is a diagram illustrating an example of a pixel array applicable to the first embodiment.

FIG. 5 is a schematic diagram illustrating an example of characteristics in a case where a blue filter and a red filter are stacked and used, which is applicable to the first embodiment.

FIG. 6 is a diagram illustrating an example of film thickness dependency of an absorption rate spectrum of Si.

FIG. 7 is a diagram illustrating an example of a relationship between an absorption rate and an Si film thickness for two wavelengths.

FIG. 8 is a schematic diagram schematically illustrating a cross section of a light receiving element according to the existing technology in a direction perpendicular to a light receiving surface.

FIG. 9 is a schematic diagram illustrating occurrence of a flare due to reflected and diffracted light emitted from a pixel according to the existing technology.

FIG. 10 is a schematic diagram illustrating an example of a flare formed in accordance with incident light from a high-luminance light source.

FIG. 11A is a diagram illustrating a configuration of an example of pixels included in an effective pixel region in a pixel array unit according to the first embodiment.

FIG. 11B is a diagram illustrating an example in which a light shielding film provided outside the pixel array unit is grounded to a semiconductor substrate according to the first embodiment.

FIG. 12 is a schematic diagram illustrating a refractive index and an extinction coefficient of crystalline silicon, amorphous silicon, and polycrystalline silicon.

FIG. 13 is a schematic diagram illustrating an example of a light intensity distribution of on-chip lenses having the same shape obtained by wave simulation.

FIG. 14 is a schematic diagram illustrating the example of the light intensity distribution of the on-chip lenses having the same shape obtained by the wave simulation.

FIG. 15 is a schematic diagram illustrating an example of a basic shape of a pinhole applicable to the first embodiment.

FIG. 16 is a schematic diagram illustrating how a removal effect for unnecessary light is obtained by the light shielding film provided with the pinhole according to the first embodiment.

FIG. 17A is a schematic diagram illustrating a method of manufacturing an example of a pixel according to the first embodiment.

FIG. 17B is a schematic diagram illustrating the method of manufacturing the example of the pixel according to the first embodiment.

FIG. 17C is a schematic diagram illustrating the method of manufacturing the example of the pixel according to the first embodiment.

FIG. 17D is a schematic diagram illustrating the method of manufacturing the example of the pixel according to the first embodiment.

FIG. 17E is a schematic diagram illustrating the method of manufacturing the example of the pixel according to the first embodiment.

FIG. 17F is a schematic diagram illustrating the method of manufacturing the example of the pixel according to the first embodiment.

FIG. 17G is a schematic diagram illustrating the method of manufacturing the example of the pixel according to the first embodiment.

FIG. 17H is a schematic diagram illustrating the method of manufacturing the example of the pixel according to the first embodiment.

FIG. 17I is a schematic diagram illustrating the method of manufacturing the example of the pixel according to the first embodiment.

FIG. 17J is a schematic diagram illustrating the method of manufacturing the example of the pixel according to the first embodiment.

FIG. 17K is a schematic diagram illustrating the method of manufacturing the example of the pixel according to the first embodiment.

FIG. 17L is a schematic diagram illustrating the method of manufacturing the example of the pixel according to the first embodiment.

FIG. 17M is a schematic diagram illustrating the method of manufacturing the example of the pixel according to the first embodiment.

FIG. 17N is a schematic diagram illustrating the method of manufacturing the example of the pixel according to the first embodiment.

FIG. 17O is a schematic diagram illustrating the method of manufacturing the example of the pixel according to the first embodiment.

FIG. 17P is a schematic diagram illustrating the method of manufacturing the example of the pixel according to the first embodiment.

FIG. 18 is a schematic diagram illustrating a structure example of the pixel according to the first embodiment in more detail.

FIG. 19 is a schematic diagram illustrating a calculation result of a case in which optimization is performed according to theoretical calculation of the Fresnel coefficient for the first embodiment.

FIG. 20 is a schematic diagram illustrating the calculation result of the case in which the optimization is performed according to the theoretical calculation of the Fresnel coefficient for the first embodiment.

FIG. 21 is a schematic diagram illustrating the calculation result of the case in which the optimization is performed according to the theoretical calculation of the Fresnel coefficient for the first embodiment.

FIG. 22 is a schematic diagram illustrating an example in which a shape of a pinhole is changed within an angle of view according to an assumed light intensity distribution according to the first embodiment.

FIG. 23 is a schematic diagram illustrating an example in which a size of the pinhole is changed within the angle of view according to the assumed light intensity distribution according to the first embodiment.

FIG. 24 is a schematic diagram illustrating a pupil correction method according to the first embodiment in comparison with a pupil correction method according to the existing technology.

FIG. 25 is a schematic diagram illustrating an application example of the pupil correction according to the first embodiment.

FIG. 26 is a schematic diagram illustrating an example of a pinhole having an area ratio of 25 [%] according to the first embodiment.

FIG. 27 is a schematic diagram illustrating a structure example of a pixel applicable to a first modification of an element separating unit of the first embodiment.

FIG. 28 is a schematic diagram illustrating a structure example of a pixel applicable to a second modification of the element separating unit of the first embodiment.

FIG. 29 is a schematic diagram illustrating a structure example of a pixel applicable to a third modification of the element separating unit of the first embodiment.

FIG. 30 is a schematic diagram illustrating a structure example of a pixel applicable to a modification of a reflection unit on a wiring layer side according to the first embodiment.

FIG. 31A is a schematic diagram illustrating an example of a method of manufacturing a metal reflecting plate, which is applicable to the first embodiment.

FIG. 31B is a schematic diagram illustrating the example of the method of manufacturing the metal reflecting plate, which is applicable to the first embodiment.

FIG. 31C is a schematic diagram illustrating the example of the method of manufacturing the metal reflecting plate, which is applicable to the first embodiment.

FIG. 31D is a schematic diagram illustrating the example of the method of manufacturing the metal reflecting plate, which is applicable to the first embodiment.

FIG. 31E is a schematic diagram illustrating the example of the method of manufacturing the metal reflecting plate, which is applicable to the first embodiment.

FIG. 31F is a schematic diagram illustrating the example of the method of manufacturing the metal reflecting plate, which is applicable to the first embodiment.

FIG. 31G is a schematic diagram illustrating the example of the method of manufacturing the metal reflecting plate, which is applicable to the first embodiment.

FIG. 31H is a schematic diagram illustrating the example of the method of manufacturing the metal reflecting plate, which is applicable to the first embodiment.

FIG. 32 is a schematic diagram illustrating a structure example of a pixel applicable to a modification of an optical waveguide applicable to the first embodiment.

FIG. 33 is a schematic diagram illustrating a structure example of a pixel applicable to a modification of a diffractive/scattering structure of the first embodiment.

FIG. 34 is a schematic diagram illustrating a structure example of a pixel applicable to a first modification of an anti-reflection film of the first embodiment.

FIG. 35 is a schematic diagram illustrating a structure example of a pixel applicable to a second modification of the anti-reflection film of the first embodiment.

FIG. 36 is a schematic diagram illustrating a structure example of a pixel applicable to a modification of an on-chip lens of the first embodiment.

FIG. 37 is a schematic diagram illustrating a structure example of a pixel applicable to a modification in which the scattering/diffractive structure is provided on the wiring layer side of the first embodiment.

FIG. 38 is a schematic diagram illustrating an example of an array of pixels provided with an optical filter, which is applicable to a second embodiment.

FIG. 39 is a schematic diagram schematically illustrating an electronic device applicable to the second embodiment, the electronic device being configured to acquire spectrum information on a subject and acquire sensing information on the subject by an IR pixel.

FIG. 40 is a cross-sectional view schematically illustrating a structure example focusing on an optical filter of a pixel, which is applicable to the second embodiment.

FIG. 41 is a schematic cross-sectional view of a pixel illustrating how to separately form a diffractive/scattering structure according to a pixel, which is applicable to the second embodiment.

FIG. 42 is a block diagram illustrating a configuration of an example of an electronic device using a distance measuring device applicable to a third embodiment.

### DESCRIPTION OF EMBODIMENTS

Hereinafter, embodiments of the present disclosure will be described in detail with reference to the drawings. It is noted that, in the following embodiments, the same portions will be denoted by the same reference numerals, and redundant description will be omitted.

Hereinafter, embodiments of the present disclosure will be described in the following order.
1. Overview of present disclosure
2. Technology applicable to first embodiment of present disclosure
2-1. Configuration example of electronic device applicable to first embodiment
2-2. Configuration example of imaging unit applicable to first embodiment
2-3. Circuit example of pixel applicable to first embodiment
2-4. Optical filter example of pixel applicable to first embodiment
3. Existing technology
4. First embodiment of present disclosure
4-0. Basic structure of pixel according to first embodiment
4-0-1. Pixel structure example according to first embodiment
4-0-2. Example of manufacturing method of pixel according to first embodiment
4-0-3. More detailed description of pixel according to first embodiment
4-1. Modification of pinhole applicable to first embodiment
4-2. Modification of light shielding film applicable to first embodiment
4-3. Modification of element separating unit applicable to first embodiment
4-4. Modification of reflection unit on wiring layer side applicable to first embodiment
4-5. Modification of optical waveguide applicable to first embodiment
4-6. Modification of diffractive/scattering structure applicable to first embodiment
4-7. Modification of anti-reflection film applicable to first embodiment
4-8. Modification of on-chip lens applicable to first embodiment
4-9. Modification including optical filter applicable to first embodiment
4-10. Modification including scattering/diffractive structure on wiring layer side applicable to first embodiment
5. Second embodiment of present disclosure
5-1. Array example of pixels provided with optical filters, which is applicable to second embodiment
6. Third embodiment of present disclosure

### 1. Overview of Present Disclosure

In a pixel as an imaging element included in a solid-state imaging device according to the present disclosure, in a structure in which a pinhole is provided between a light receiving surface and an on-chip lens provided on the light receiving surface, the on-chip lens is made of silicon. The silicon forming the on-chip lens may be polycrystalline silicon or amorphous silicon. Silicon has a refractive index of approximately 3.4 to 3.8 with respect to light having a wavelength in a visible light region or an infrared region, and the refractive index is higher than a refractive index n of a general on-chip lens. Therefore, the beam waist of incident light can be further narrowed, and a pinhole diameter can be reduced.

By reducing the pinhole diameter, light incident on an imaging element can be easily confined inside the imaging element, and utilization efficiency of the incident light inside the imaging element can be increased, thereby making it possible to achieve higher sensitivity.

### 2. Technology Applicable to First Embodiment of Present Disclosure

Next, technology applicable to a first embodiment of the present disclosure will be described.

(2-1. Configuration Example of Electronic Device Applicable to First Embodiment)

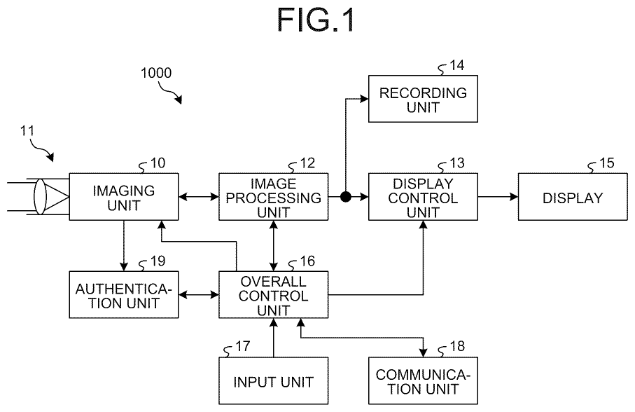

FIG. 1 is a block diagram illustrating a configuration of an example of an electronic device applicable to the first embodiment of the present disclosure. In FIG. 1, An electronic device 1000 includes an imaging unit 10, an optical unit 11, an image processing unit 12, a display control unit 13, a recording unit 14, a display 15, an overall control unit 16, an input unit 17, a communication unit 18, and an authentication unit 19. The overall control unit 16 includes a processor such as a central processing unit (CPU), for example, and controls the overall operation of the electronic device 1000 according to a program.

The optical unit 11 includes one or more lenses, a focus mechanism, a diaphragm mechanism, and the like, and guides light from a subject to the imaging unit 10. Among the lenses included in the optical unit 11, for example, a lens disposed at a position closest to the imaging unit 10 is referred to as a main lens.

The imaging unit 10 includes a solid-state imaging device having a pixel array in which pixels 100 are disposed in a matrix, generates a pixel signal according to light incident via the optical unit 11, converts the generated pixel signal into pixel data which is a digital signal, and outputs the pixel data.

The pixel data output from the imaging unit 10 is supplied to the image processing unit 12 and the authentication unit 19. The image processing unit 12 performs image processing for display such as white balance adjustment processing and gamma correction processing on the supplied image data by the pixel data for one frame, and outputs the image data. The image data output from the image processing unit 12 is supplied to the display control unit 13 and the recording unit 14.

The display control unit 13 controls display of an image based on the supplied image data on the display 15. Further, the image data output from the image processing unit 12 is also supplied to the recording unit 14. The recording unit 14 includes a nonvolatile recording medium such as a hard disk drive or a flash memory, and records the supplied image data in the recording medium. The present disclosure is not limited thereto, and the image data output from the image processing unit 12 can also be output to the outside of the electronic device 1000.

The input unit 17 receives a user operation and transmits a signal corresponding to the user operation to the overall control unit 16. The overall control unit 16 can control the operation of the electronic device 1000 according to the signal transmitted from the input unit 17. It is noted that the input unit 17 may be integrated with the display 15 to form a so-called touch panel.

The communication unit 18 communicates with an external device by, for example, wireless communication under the control of the overall control unit 16.

The authentication unit 19 performs, for example, recognition processing of recognizing a user based on the image data supplied from the imaging unit 10. As an example, the authentication unit 19 performs authentication processing as follows. The authentication unit 19 detects the user's face based on the image data and obtains a feature amount of the detected face. The authentication unit 19 compares a feature amount of the face of the user registered in advance with the feature amount of the user's face detected from the image data to obtain similarity therebetween, and authenticates the user when the obtained similarity is equal to or greater than a threshold value. The authentication result by the authentication unit 19 is transmitted to the overall control unit 16.

In a case where the recognition result transmitted from the authentication unit 19 indicates failure of authentication, the overall control unit 16 may restrict, for example, a function that can be operated by the user in the electronic device 1000. As an example, in a case where the authentication result indicates the authentication failure of the user, the overall control unit 16 may instruct the display control unit 13 to lock the display on the display 15, and may restrict the user operation received by the input unit 17.

(2-2. Configuration Example of Imaging Unit Applicable to First Embodiment)

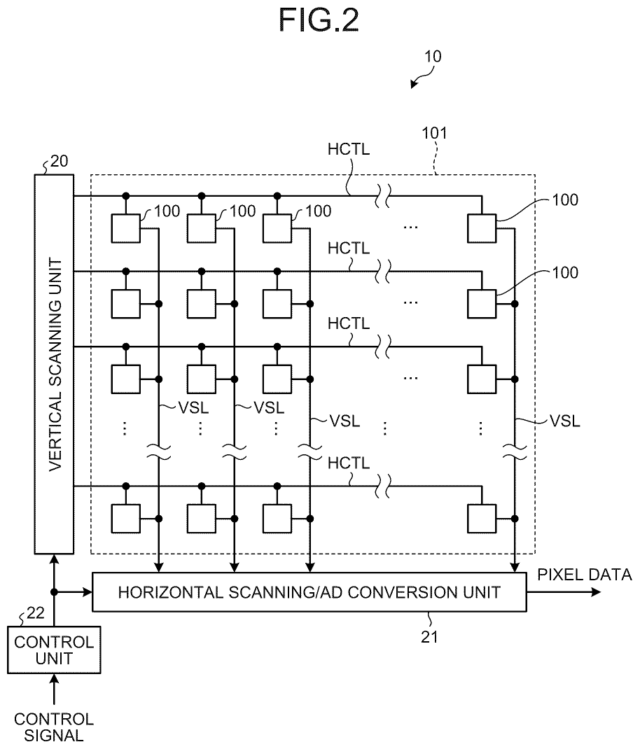

FIG. 2 is a block diagram illustrating a configuration of an example of the imaging unit applicable to the first embodiment. In FIG. 2, the imaging unit includes a pixel array unit 101, a vertical scanning unit 20, a horizontal scanning/AD conversion unit 21, and a control unit 22.

The pixel array unit 101 includes a plurality of pixels 100 each having an imaging element that generates a voltage corresponding to received light. As the imaging element, a photodiode can be used. In the pixel array unit 101, the plurality of pixels 100 are arranged in a matrix in a horizontal direction (row direction) and a vertical direction (column direction). In the pixel array unit 101, the arrangement of the pixels 100 in the row direction is referred to as a line. An image (image data) of one frame is formed based on pixel signals read from a predetermined number of lines in the pixel array unit 101. For example, in a case where an image of one frame is formed with 3000 pixels×2000 lines, the pixel array unit 101 includes at least 2000 lines including at least 3000 pixels 100.

It is noted that, in the pixel array unit 101, a region including the pixels 100 used to form the image of one frame is referred to as an effective pixel region. Furthermore, in the pixel array unit 101, a region including the pixels 100 that are not used to form the image of one frame is referred to as an ineffective pixel region.

In addition, in the pixel array unit 101, with respect to a row and a column of each pixel 100, a pixel signal line HCTL is connected to each row, and a vertical signal line VSL is connected to each column.

An end portion of the pixel signal line HCTL that is not connected to the pixel array unit 101 is connected to the vertical scanning unit 20. For example, the vertical scanning unit 20 transmits a plurality of control signals such as a drive pulse at the time of reading a pixel signal from the pixel 100 to the pixel array unit 101 via the pixel signal line HCTL according to a control signal supplied from the control unit 22. An end portion of the vertical signal line VSL that is not connected to the pixel array unit 101 is connected to the horizontal scanning/AD conversion unit 21.

The horizontal scanning/AD conversion unit 21 includes an analog to digital (AD) conversion unit, an output unit, and a signal processing unit. The pixel signal read from the pixel 100 is transmitted to the AD conversion unit of the horizontal scanning/AD conversion unit 21 via the vertical signal line VSL.

The reading control of the pixel signal from the pixel 100 will be schematically described. Reading the pixel signal from the pixel 100 is performed by transferring charges accumulated in the imaging element by exposure to a floating diffusion (FD) layer and converting the charges transferred in the floating diffusion layer into a voltage. The voltage obtained by converting the charges in the floating diffusion layer is output to the vertical signal line VSL via an amplifier.

More specifically, in the pixel 100, during exposure, a space between the imaging element and the floating diffusion layer is set to an off (open) state, and charges generated according to light incident by photoelectric conversion are accumulated in the imaging element. After the exposure is completed, the floating diffusion layer and the vertical signal line VSL are connected according to a selection signal supplied via the pixel signal line HCTL. Further, the floating diffusion layer is connected to a supply line of a power supply voltage VDD or a black level voltage in a short period of time according to a reset pulse supplied via the pixel signal line HCTL, and the floating diffusion layer is reset. A voltage (referred to as a voltage P) of a reset level of the floating diffusion layer is output to the vertical signal line VSL. Thereafter, the space between the imaging element and the floating diffusion layer is turned on (closed) by a transfer pulse supplied via the pixel signal line HCTL, and the charges accumulated in the imaging element are transferred to the floating diffusion layer. A voltage (referred to as a voltage Q) corresponding to the charge amount of the floating diffusion layer is output to the vertical signal line VSL.

In the horizontal scanning/AD conversion unit 21, the AD conversion unit includes an AD converter provided for each vertical signal line VSL, the pixel signal supplied from the pixel 100 via the vertical signal line VSL is subjected to AD conversion processing by the AD converter, and two digital values (values respectively corresponding to the voltage P and the voltage Q) for correlated double sampling (CDS) processing of reducing noise are generated.

The two digital values generated by the AD converter are subjected to CDS processing by the signal processing unit, and a pixel signal (pixel data) by a digital signal is generated. The generated pixel data is output from the imaging unit.

Under the control of the control unit 22, the horizontal scanning/AD conversion unit 21 performs selective scanning for selecting the AD converters for the respective vertical signal lines VSL in a predetermined order, thereby sequentially outputting the respective digital values temporarily stored in the respective AD converters to the signal processing unit. The horizontal scanning/AD conversion unit 21 implements this operation by a configuration including, for example, a shift register, an address decoder, and the like.

The control unit 22 performs, for example, drive control of the vertical scanning unit 20, the horizontal scanning/AD conversion unit 21, and the like in accordance with a control signal from the overall control unit 16. The control unit 22 generates various drive signals serving as references for operations of the vertical scanning unit 20 and the horizontal scanning/AD conversion unit 21. The control unit 22 generates a control signal that the vertical scanning unit 20 supplies to each pixel 100 via the pixel signal line HCTL based on a vertical synchronization signal or an external trigger signal supplied from the outside (for example, the control unit 22) and a horizontal synchronization signal. The control unit 22 supplies the generated control signal to the vertical scanning unit 20.

Based on the control signal supplied from the control unit 22, the vertical scanning unit 20 supplies various signals including the drive pulse to the pixel signal line HCTL of the selected pixel row of the pixel array unit 101 to each pixel 100 line by line, and causes each pixel 100 to output the pixel signal to the vertical signal line VSL. The vertical scanning unit 20 is configured using, for example, a shift register, an address decoder, and the like.

The imaging unit configured as described above is a column AD system complementary metal oxide semiconductor (CMOS) image sensor in which AD converters are arranged for each column.

(2-3. Circuit Example of Pixel Applicable to First Embodiment)

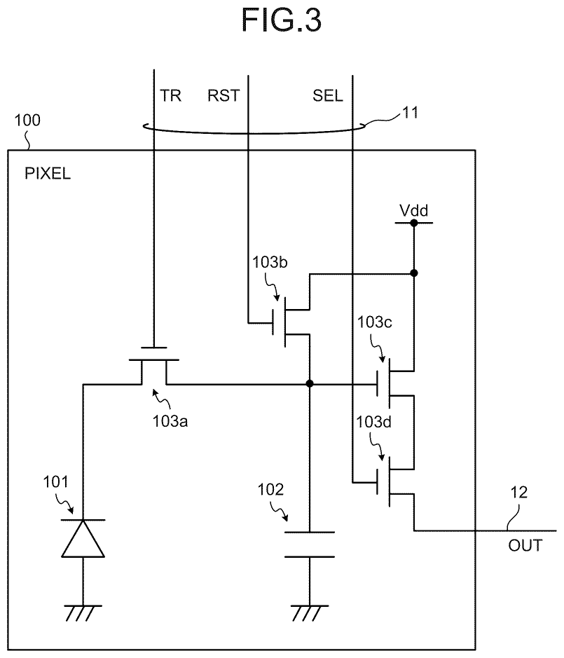

FIG. 3 is a circuit diagram illustrating a circuit of an example of a pixel applicable to the first embodiment. In FIG. 3, the pixel 100 includes a charge holding unit 102, MOS transistors 103a to 103d, and a photoelectric conversion unit 121. An anode of the photoelectric conversion unit 121 is grounded, and a cathode thereof is connected to a source of the metal oxide semiconductor (MOS) transistor 103a. A drain of the MOS transistor 103a is connected to a source of the MOS transistor 103b, a gate of the MOS transistor 103c, and one end of the charge holding unit 102. The other end of the charge holding unit 102 is grounded.

Drains of the MOS transistors 103c and 103d are commonly connected to a power supply line Vdd, and a source of the MOS transistor 103c is connected to the drain of the MOS transistor 103d. A source of the MOS transistor 103d is connected to an output signal line OUT. Gates of the MOS transistors 103a, 103b, and 103d are connected to a transfer signal line TR, a reset signal line RST, and a selection signal line SEL, respectively.

It is noted that the transfer signal line TR, the reset signal line RST, and the selection signal line SEL form the pixel signal line HCTL. Further, the output signal line OUT is connected to the vertical signal line VSL. The photoelectric conversion unit 121 generates a charge corresponding to the received light by photoelectric conversion. A photodiode can be used as the photoelectric conversion unit 121. Furthermore, the charge holding unit 102 and the MOS transistors 103a to 103d form a pixel circuit.

The MOS transistor 103a is a transistor that transfers a charge generated by photoelectric conversion of the photoelectric conversion unit 121 to the charge holding unit 102. The transfer of the charge in the MOS transistor 103a is controlled by a signal transmitted by the transfer signal line TR.

The charge holding unit 102 is a capacitor that holds the charge transferred by the MOS transistor 103a. The MOS transistor 103c is a transistor that generates a signal based on the charge held in the charge holding unit 102. The MOS transistor 103d is a transistor that outputs a signal generated by the MOS transistor 103c to the output signal line OUT as an image signal. The MOS transistor 103d is controlled by a signal transmitted by the selection signal line SEL.

The MOS transistor 103b is a transistor that resets the charge holding unit 102 by discharging the charge held in the charge holding unit 102 to the power supply line Vdd. The reset by the MOS transistor 103b is controlled by a signal transmitted by the reset signal line RST, and the same is executed before the charge is transferred by the MOS transistor 103a. At the time of this reset, the photoelectric conversion unit 121 can also be reset by allowing the MOS transistor 103a to be conductive. In this manner, the pixel circuit converts the charge generated by the photoelectric conversion unit 121 into an image signal.

It is noted that, in the following description, in a case where it is not necessary to distinguish the MOS transistors 103a to 103d, the MOS transistor 103 will be used as a representative for description.

(2-4. Example of Optical Filter of Pixel Applicable to First Embodiment)

Next, an example of an optical filter of the pixel applicable to the first embodiment will be described. Here, the first embodiment of the present disclosure is applicable to a solid-state imaging device in which at least some of the plurality of pixels 100 included in the imaging unit 10 receive light having a wavelength longer than a wavelength in a visible light region.

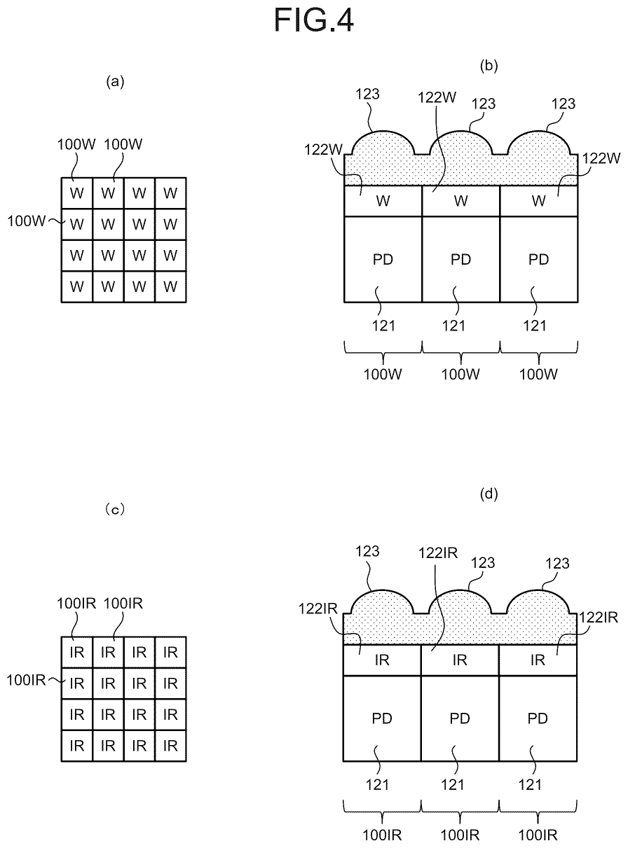

FIG. 4 is a diagram illustrating an example of a pixel array applicable to the first embodiment. In a section (a) of FIG. 4, for example, pixels 100W respectively including filters 122W (white filter) configured to allow visible light and infrared light to be transmitted therethrough with a transmittance of a certain level or more are repeatedly arranged.

A section (b) of FIG. 4 is a simplified cross-sectional view illustrating a structure example of the pixel 100W. It is noted that the pixel 100W can also achieve an effect equivalent to that in a case where the filter 122W is provided by not providing an optical filter. From the viewpoint of cost, it is desirable that there is no optical filter, and the filter 122W may be provided for other purposes such as elimination of a step or optical design using a refractive index.

In a section (c) of FIG. 4, for example, pixels 100IR respectively including filters 122IR (hereinafter, an IR filter) configured to allow infrared light to be selectively transmitted therethrough are repeatedly arranged. With this arrangement, external light noise in the visible light region can be shielded, and an SN ratio can be improved.

A section (d) of FIG. 4 is a simplified cross-sectional view illustrating a structure example of the pixel 100IR. The filter 122IR may be, for example, an organic material containing a pigment or a dye, and for example, an organic material known in Patent Literature 4 may be used. The filter 122IR may be a band pass filter of a narrow band adapted to a wavelength of specific infrared light of a light source unit 70 instead of a wide range of infrared light. By aligning the transmission spectrum of a filter with a light source wavelength, external light noise can be shielded, and the SN ratio can be improved.

The filter 122IR may be provided by stacking organic materials containing two different types of pigments and dyes. As an example, a description will be given as to a case in which a blue filter configured to allow light in a blue wavelength region to be transmitted therethrough and a red filter configured to allow light in a red wavelength region to be transmitted therethrough are stacked and used.

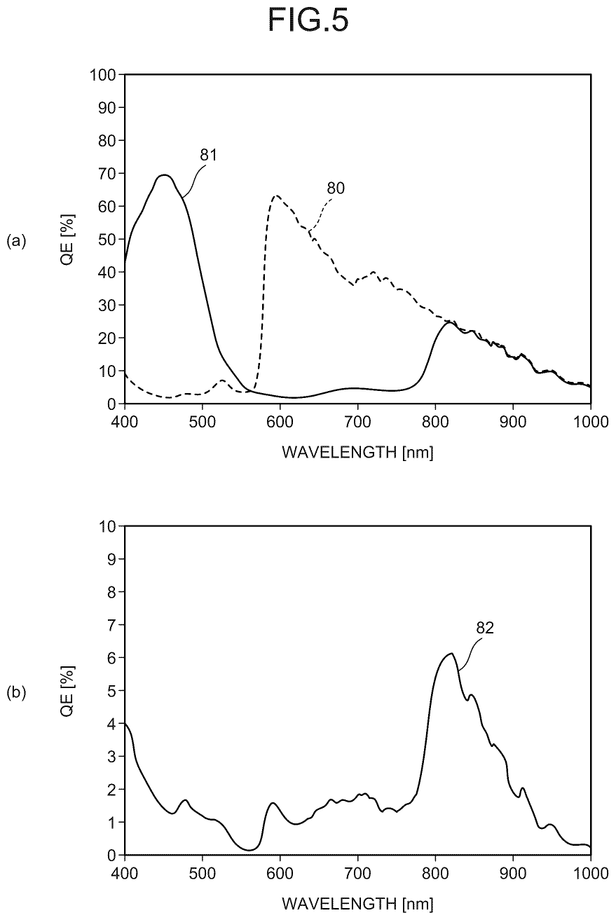

FIG. 5 is a schematic diagram illustrating an example of characteristics in a case where the blue filter and the red filter are stacked and used, which is applicable to the first embodiment. In FIG. 5, a section (a) illustrates an example of wavelength dependency of quantum efficiency (QE) for each of the red filter (characteristic line 80) and the blue filter (characteristic line 81). In addition, a section (b) illustrates an example (characteristic line 82) of the wavelength dependency of QE in a case in which the red filter and the blue filter having the characteristics illustrated in the section (a) are stacked.

In the example of FIG. 5, the transmission spectrum unique to a common base resin exists in the infrared region including the wavelength region of 780 [nm] to 1000 [nm]. Therefore, even when the blue filter and the red filter are stacked, light in the common wavelength region is easily transmitted, and different pigments contained in the respective materials act and are absorbed complementarily in the visible light region. That is, the stacked filters allow infrared light to be selectively transmitted therethrough.

It is noted that the combination of the stacked filters is not limited to this example, and for example, filters in a complementary color relationship such as cyan and red, magenta and green, and yellow and blue may be combined to absorb visible light.

It is noted that, hereinafter, the pixel 100IR including the IR filter may be referred to as an IR pixel. Furthermore, the pixel 100 including an optical filter configured to allow light in the wavelength region of visible light such as red, green, and blue to be selectively transmitted therethrough may be referred to as a visible light pixel.

### 3. Existing Technology

Next, prior to the description of the first embodiment according to the present disclosure, an existing technology will be schematically described in order to facilitate understanding. In the pixel 100, the photoelectric conversion unit 121 is formed in a silicon (Si) substrate. Since Si is an indirect transition type semiconductor and has a bandgap of 1.1 [eV], the same has sensitivity to a wavelength of near infrared rays having a wavelength of about 1.1 [μm] from a wavelength in a visible light region. On the other hand, due to the wavelength dependency of the light absorption coefficient of Si, the longer the wavelength, the smaller the light absorption coefficient per unit thickness, so that most of photons of long-wavelength light incident on an Si layer are transmitted through the Si layer.

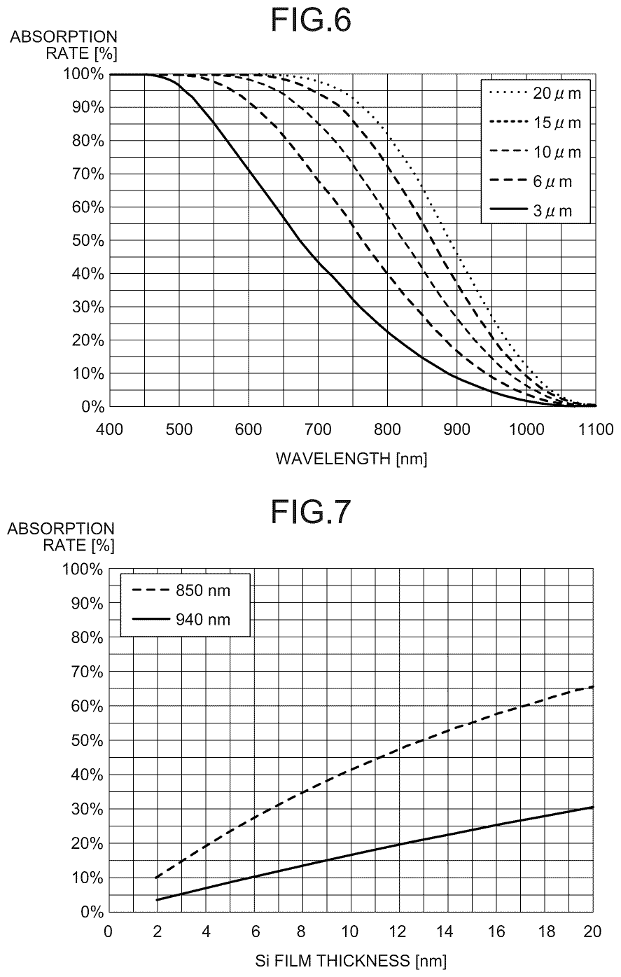

FIG. 6 is a diagram illustrating an example of film thickness dependency of an absorption rate spectrum of Si. In FIG. 6, the film thickness indicated by each characteristic line is described in the upper right. As illustrated in FIG. 6, for example, in the case of a solid-state imaging element in which the thickness of an Si layer as a light absorption layer is 3 [μm], the light absorption efficiency at a wavelength λ of 650 [nm] is about 57 [%], the light absorption efficiency at a wavelength λ of 940 [nm] is about 5 [%], and most of photons transmit through the Si layer. Therefore, in order to implement a solid-state imaging element having high sensitivity to infrared light, it is known as an effective method to increase the thickness of the Si layer.

FIG. 7 is a diagram illustrating an example of a relationship between an absorption rate and an Si film thickness for two wavelengths (850 [nm], 940 [nm]). As illustrated in FIG. 7, it can be seen that, for both wavelengths, the absorption rate increases as the Si film thickness increases.

In order to improve the sensitivity to light having a long wavelength, a method of increasing the thickness of the Si layer is considered. However, in the case of increasing the thickness of the Si layer, it is necessary to perform high-energy implantation in order to implement a desired impurity profile, which increases the difficulty in manufacturing and costs. In addition, an increase in defects in the crystal due to an increase in the thickness of the Si layer may cause deterioration in dark time characteristics such as an increase in dark current and generation of white spots. Furthermore, when the ratio of the thickness of the light receiving element to the pixel size increases, element separation enhancement of measures against a color mixture component of an Si bulk in the Si layer is required, the processing difficulty level increases, the number of processes increases, and there is a risk of causing an increase in cost and deterioration in dark time characteristics.

Therefore, as a method of obtaining high sensitivity to light on the long wavelength side in the light receiving element, a structure in which a reflecting surface is provided on the opposite side of the light receiving surface of the element has been proposed (for example, Patent Literature 2). In addition, a structure has been proposed in which a pattern of periodic unevenness is provided on the light receiving surface to lengthen an optical path length of high-order diffracted light, a pattern of periodic unevenness is also provided on the substrate surface on the opposite side of the light receiving surface with respect to 0th-order light, and the optical path length is lengthened by a diffraction phenomenon of a reflected wave (for example, Patent Literature 3).

A structure in which light transmitted through the Si layer is returned to the Si layer as described in Patent Literature 2 or Patent Literature 3 increases a reflection component from the light receiving element, and a flare may occur in a captured image. For example, light reflected inside the light receiving element is emitted to the light receiving surface side of the light receiving element, the emitted light is further reflected by an optical filter, a main lens, or the like provided on the light receiving surface side of the light receiving element, and the same is incident on another light receiving element, which causes a flare.

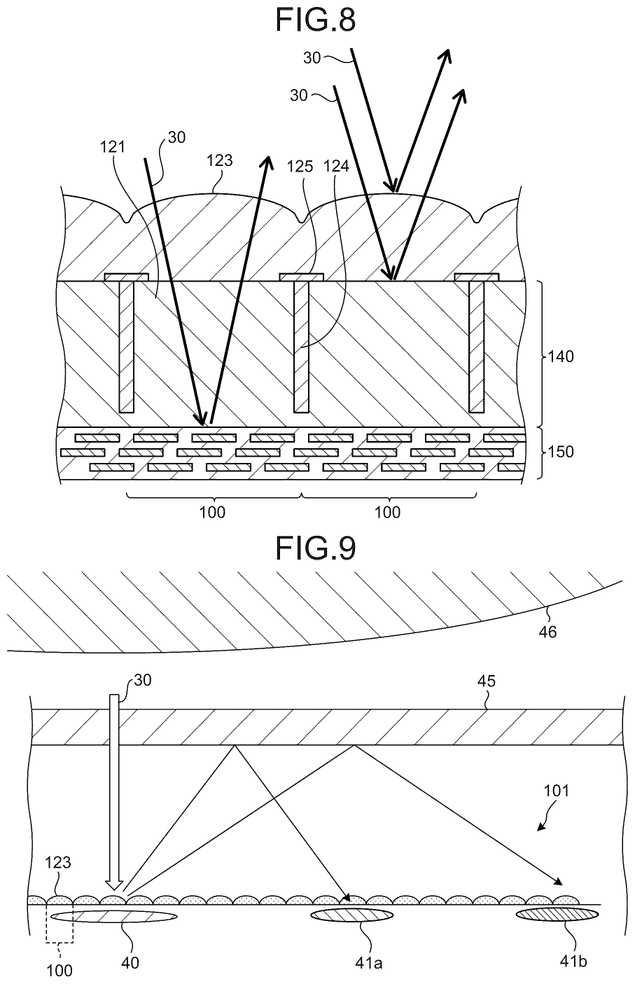

With reference to FIGS. 8 and 9, a description will be given as to occurrence of a flare due to light reflected inside the light receiving element. FIG. 8 is a schematic diagram schematically illustrating a cross section of a light receiving element according to the existing technique in a direction perpendicular to a light receiving surface. In FIG. 8, in the pixel 100, an on-chip lens 123 is provided on the light receiving surface side with respect to a silicon (Si) layer (a semiconductor substrate 140) in which the photoelectric conversion unit 121 is formed, and a wiring layer 150 is provided on the surface on the opposite side of the light receiving surface. Furthermore, in the pixel 100, an element separating unit 124 having a trench structure is provided at a boundary portion with another adjacent pixel 100. Furthermore, the pixel 100 has an anti-reflection film 125 provided at a boundary portion with another adjacent pixel 100, with respect to the light receiving surface.

A case where external light 33 from a high-luminance light source such as sunlight is incident on the pixel 100 having such a structure will be considered. In general, in a case where light is perpendicularly incident on a medium having a refractive index refractive index n₁ from a medium having a refractive index n₀, reflectance R at an interface is formulated by the following Equation (1). According to Equation (1), it can be seen that reflection easily occurs at an interface having a large difference in refractive index.

R=(n₀−n₁)²/(n₀+n₁)² (1)

In the case of a back surface irradiation type solid-state imaging device, a difference in refractive index at the following three types of interfaces increases.
(a) Surface of on-chip lens
(b) Surface of silicon substrate on light receiving surface side
(c) Surface on opposite side of light receiving surface of silicon substrate

From the viewpoint of flare suppression, it is desirable to apply anti-reflection design to any one of the interfaces (a), (b), and (c) described above. As an example of anti-reflection design, an anti-reflection film is formed on an interface of a material having a low refractive index with a film thickness in accordance with the λ/(4n) rule. The above (a) and (b) are advantageous from the viewpoint of higher sensitivity in addition to suppression of a flare.

However, with respect to the interface of (c), since light escapes from a photoelectric conversion film, it is desirable to reflect the escaping light back to the photoelectric conversion unit from the viewpoint of high sensitivity. On the other hand, the anti-reflection design of the interface of (c) at the flare viewpoint is desirable, and the flare and the sensitivity fall into a trade-off relationship.

FIG. 9 is a schematic diagram illustrating occurrence of a flare due to reflected and diffracted light emitted from the pixel 100 according to the existing technology. When incident light 30 from a high-luminance light source is reflected in an image circle of a module lens at the time of photographing, light with a wavelength λ generates diffracted light that is intensified at an angle θ of satisfying the following Equation (2) in a case where a pixel pitch period or an array period of a color filter is defined as d, and the order n of the diffracted light is defined as an integer of 0, ±1, ±2, and so on. In the solid-state imaging device, since pixels are arranged in a two-dimensional lattice pattern, and a two-dimensional periodic pattern is formed, the order of the diffracted light is also represented in two dimensions.

d×sin θ=nλ (2)

Reflected and diffracted light from the solid-state imaging device reinforced in this manner is re-reflected by an optical member 45 such as a band pass filter located on the light incident side of the solid-state imaging device, and the same is incident again on the pixel array unit 101 to be reflected as a flare.

For example, in a case where the optical member 45, which is a band pass filter, is formed of a laminated film of a plurality of materials having different refractive indices, a flare due to light near a cutoff wavelength occurs in a spot shape due to deviation of the cutoff wavelength toward a short wavelength side due to oblique incidence. For example, it is assumed that a wavelength λ is 940 [nm], a pixel period d is 3 [μm], and a distance between the optical member 45, which is, for example, a band pass filter, and the solid-state imaging device is 1 [mm]. In this case, first-order diffracted light is generated at the angle of 18.3°, and second-order diffracted light is generated at the angle of 38.8°. By re-reflection of the optical member 45, a first-order spot 41a is generated at a position of about 660 [μm] from a light source image 40, and a second-order spot 41b is generated at a position of 1608 [μm] from the light source image 40.

On the other hand, in a case where an absorption type band pass filter serves as an interface, or in a case where the lower surface of a module lens serves as a reflecting surface without including a band pass filter, a diffraction angle changes for each wavelength, and a streak-like flare occurs radially from the light source image 40.

For example, in a face authentication function used in a smartphone, infrared light is emitted toward a user side, reflected light is received by a solid-state imaging element corresponding to near infrared rays, a face's feature is extracted, and the face is collated with registered owner information to determine whether the user is the person himself or herself. The authentication action by the smartphone is also performed outdoors.

As an example, consideration is given as to a case in which a high-luminance light source such as sunlight is present in the background when the user's face is captured by a sensor provided in the smartphone in a state in which the smartphone is oriented upwards.

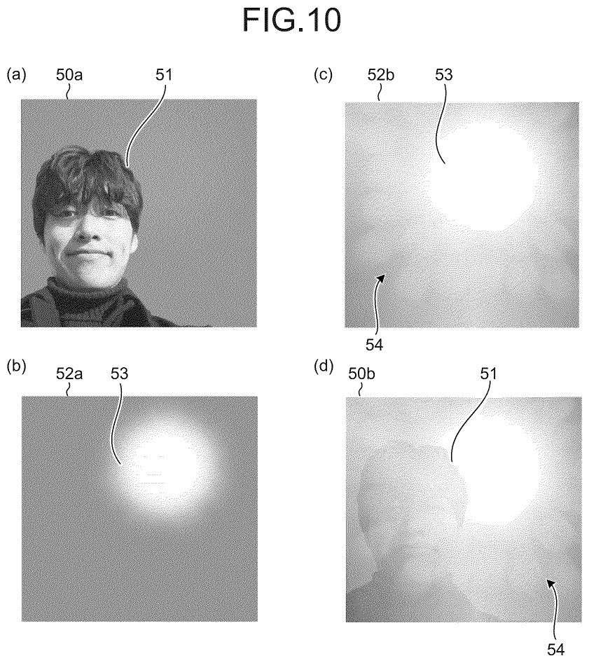

FIG. 10 is a schematic diagram illustrating an example of a flare formed in accordance with the incident light 30 from a high-luminance light source. A section (a) illustrates an example of a normal authentication image 50a of the face authentication in the smartphone. It can be seen that a face 51 to be authenticated is clearly included in the authentication image 50a. Sections (b) and (c) illustrate examples of images 52a and 52b showing only an image 53 of the sun for understanding the phenomenon of a flare. In contrast to the original image 53 of the sun included in the image 52a illustrated in the section (b), in the image 52b illustrated in the section (c), countless spots and overall output floats are reflected around the image 53 of the sun, which is a high-luminance light source. Spots 54 and output floats for the high-luminance light source are a phenomenon called a flare. A section (d) illustrates an example of authentication image 50b in which sunlight exists in the background of the face 51 and a flare is reflected on the face 51 when the face 51 of the user is captured in a state in which the smartphone is oriented upwards.

As described above, there is a possibility that stray light derived from the high-luminance light source reflected inside the solid-state imaging device or the like is re-reflected by the optical member 45 such as the main lens or the filter or the reflecting surface of a smartphone housing or the like, and the same is reflected as a ghost component such as a flare in the imaging region of the face 51 of the subject. This flare may cause an authentication error and impair convenience of the authentication function of the smartphone.

This problem is a trade-off behavior of characteristics, that is, “if the surface on the opposite side of the light receiving surface is provided with a reflection function for high sensitivity, a flare deteriorates” in the light receiving element, and that “sensitivity decreases when an absorption function is provided on the surface on the opposite side of the light receiving surface in order to suppress a flare”.

As a means for solving this trade-off behavior of characteristics, proposed is a structure in which, in a light receiving element included in a solid-state imaging device, a reflection structure is provided on a surface on the opposite side of a light receiving surface, a pinhole is provided between an on-chip lens and a substrate (Si layer), and reflected light by the surface on the opposite side of the light receiving surface is confined in the Si layer (for example, Patent Literature 1).

However, when the Fraunhofer diffraction equation is developed to have a wavelength λ, a refractive index n of a medium, a focal length f, and a lens size D, a beam waist ω₀ of light condensed by a lens spreads in proportion to the wavelength λ according to a physical rule of the following Equation (3), and as such, it is difficult to narrow infrared light so as to pass through an opening portion formed by a pinhole.

ω₀=1.22fλ/nD (3)

Furthermore, in a case where there is a crosstalk path between the Si layer and the pinhole as in Patent Literature 1, there is also a possibility that the incident light 30 leaks into an adjacent pixel, resulting in deterioration of resolution.

### 4. First Embodiment of Present Disclosure

Next, the first embodiment of the present disclosure will be described.

(4-0. Basic Structure of Pixel According to First Embodiment)

(4-0-1. Pixel Structure Example According to First Embodiment)

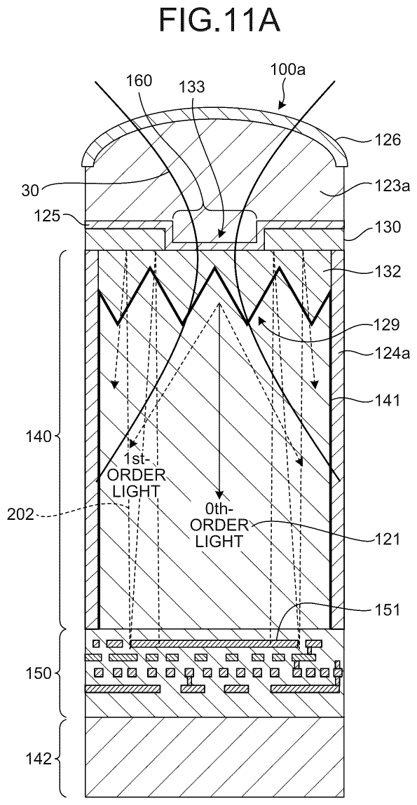

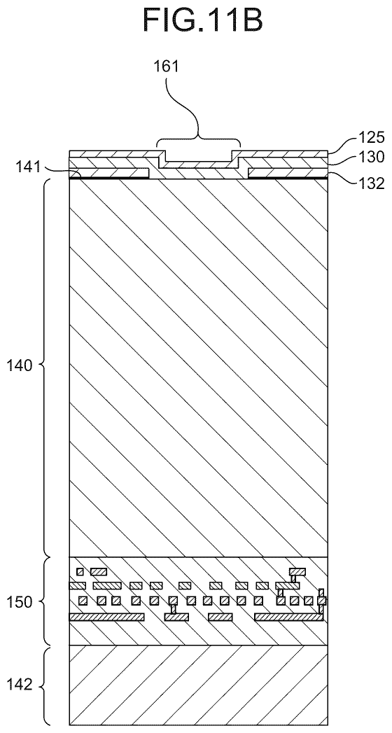

A structure of a pixel according to the first embodiment will be described with reference to FIGS. 11A and 11B. FIGS. 11A and 11B are cross-sectional views illustrating a configuration of an example of the pixel according to the first embodiment in a cross section in a direction perpendicular to the light receiving surface. FIG. 11A is a diagram illustrating a configuration of an example of a pixel 100a included in the effective pixel region in the pixel array unit 101 according to the first embodiment. Furthermore, FIG. 11B is a diagram illustrating an example in which a light shielding film 130 provided outside the pixel array unit 101 is grounded to the semiconductor substrate 140 according to the first embodiment. It is noted that each of FIGS. 11A and 11B is illustrated as a cross-sectional view illustrating a cross section in a direction perpendicular to the light receiving surface.

FIG. 11A illustrates an example of a pixel in a back surface irradiation type solid-state imaging device, in which the back surface side of the semiconductor substrate 140 is oriented upwards to form an on-chip lenses 123a, and the front surface side of the semiconductor substrate 140 on which the wiring layer 150 to be described later is formed is oriented downwards. The structure illustrated in FIG. 11B also conforms to the structure with the back surface irradiation type.

The pixel 100a includes the semiconductor substrate 140, the photoelectric conversion unit 121, the MOS transistor 103, the light shielding film 130, the on-chip lenses 123a, a pinhole 160 (hole portion) provided in the light shielding film 130, an element separating unit 124a, the wiring layer 150, a support substrate 142, and an insulating film 132. The pixel 100a desirably further includes a fixed charge film 141, the anti-reflection film 125, an anti-reflection film 126, an optical waveguide 133, and the like.

Furthermore, the pixel 100a may include a diffractive/scattering structure 129, a reflection unit 151, and the like.

The semiconductor substrate 140 is, for example, a silicon (Si) substrate or a compound semiconductor substrate such as indium gallium arsenide (InGaAs), and includes the photoelectric conversion unit 121 and a plurality of pixel transistors (for example, MOS transistors 130a to 130d) for each pixel 100a.

The photoelectric conversion unit 121 is formed over the entire region in the thickness direction of the semiconductor substrate 140, and is configured as a p-n junction type photodiode of a first conductivity type, in this example, an n-type semiconductor region for convenience, and a second conductivity type, in this example, a p-type semiconductor region so as to face both front and back surfaces of the substrate. The p-type semiconductor region facing both the front and back surfaces of the substrate also serves as a hole charge accumulation region for suppressing dark current. Each pixel 100a is separated by the element separating unit 124a.

The fixed charge film 141 has a negative fixed charge due to a dipole of oxygen, may be provided so as to be in contact with the surface of the semiconductor substrate 140, and plays a role of reinforcing pinning of the photoelectric conversion unit 121.

The fixed charge film 141 can be formed of, for example, an oxide or nitride containing at least one of hafnium, aluminum (Al), zirconium, thallium (Ta), and titanium (Ti). The fixed charge film 141 can also be formed of an oxide or nitride containing at least one of lanthanum, cerium, neodymium, promethium, samarium, europium, gadolinium, terbium, dysprosium, holmium, thulium, ytterbium, lutetium, and yttrium.

Further, the fixed charge film 141 can also be formed of hafnium oxynitride or aluminum oxynitride. Furthermore, silicon or nitrogen can be added to the fixed charge film 141 in an amount that does not impair the insulating properties. Accordingly, heat resistance and the like can be improved. It is desirable that the fixed charge film 141 has a film thickness controlled in consideration of a wavelength and a refractive index, and has a role as an anti-reflection film for the semiconductor substrate 140 having a high refractive index.

Each MOS transistor 103 illustrated in FIG. 3 is configured by forming an n-type source region and a drain region in a p-type semiconductor well region formed on the front surface side of the semiconductor substrate 140, and forming a gate electrode on the substrate surface between the source region and the drain region via a gate insulating film.

The light shielding film 130 is provided on the light receiving surface side of the semiconductor substrate 140 in the pixel 100a with the fixed charge film 141, the insulating film 132, and the like interposed therebetween, and has the pinhole 160 (hole portion) provided therein.

The light shielding film 130 is preferably formed of a metal film such as Al, tungsten (W), or copper as a material having a strong light shielding property and capable of being accurately processed by fine processing such as etching. In addition, the light shielding film 130 can be formed of silver, gold, platinum, molybdenum (Mo), chromium (Cr), Ti, nickel (Ni), iron, tellurium, or the like, or an alloy containing these metals. A barrier metal having a high melting point material such as Ti, Ta, W, cobalt (Co), Mo, an alloy thereof, a nitride thereof, an oxide thereof, or a carbide thereof may be provided between the light shielding film 130 and a layer in contact with the light shielding film 130. By providing the barrier metal, adhesion to the layer in contact with the barrier metal can be enhanced.

Furthermore, the light shielding film 130 may also serve as light shielding of a pixel for determining an optical black level, or may also serve as light shielding for preventing noise to a peripheral circuit region. The light shielding film 130 is desirably grounded so as not to be destroyed by plasma damage due to accumulated charges during processing. A ground structure of the light shielding film 130 may be formed in the pixel array, but the ground structure may be provided outside the effective pixel region such as the pixel 100 or the pixel for determining the black level after all the light shielding films 130 are electrically connected to each other. The processing damage of the light receiving side surface layer of the photoelectric conversion unit 121 can be avoided by providing the ground structure outside the effective pixel region.

The on-chip lens 123a is formed of silicon as a material, and focuses incident light from a module lens on the pinhole 160 so that the incident light is not vignetted by the light shielding film 130 around the pinhole 160. The light transmitted through the pinhole 160 by the on-chip lens 123a is photoelectrically converted by the photoelectric conversion unit 121.

As the silicon used in the on-chip lens 123a, amorphous silicon (hereinafter, α-Si is appropriately described) or polycrystalline silicon can be applied. In α-Si, the structure of crystalline silicon originally having a diamond structure is random, and silicon atoms are randomly bonded to each other. Although α-Si is a thermodynamically unstable substance as compared with crystalline silicon, the same becomes a stable solid by bonding hydrogen to a dangling bond. In addition, there is an advantage in that a film can be formed at a lower temperature (for example, 200° C. to 400° C.) than crystalline silicon, and a film can be easily formed on an amorphous material or a material that cannot withstand a high temperature. On the other hand, polycrystalline silicon has a polycrystalline structure in which crystal grains of about several hundreds [nm] are densely bonded to each other.

In FIG. 11B, the light shielding film 130 is configured to penetrate the insulating film 132 and the fixed charge film 141 in a region 161 so as to be in contact with the semiconductor substrate 140. As described above, on the outer side of the pixel array unit 101, a region to be grounded by allowing the metal light shielding film 130 to contact the semiconductor substrate 140 is provided.

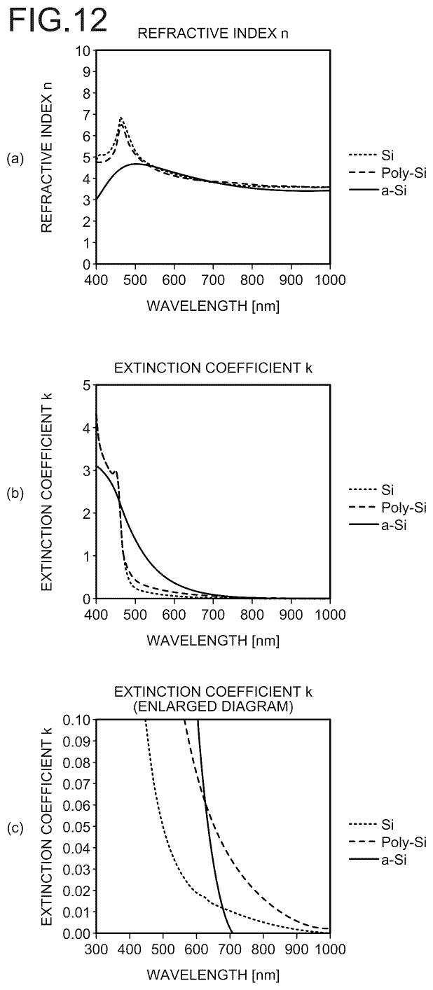

FIG. 12 is a schematic diagram illustrating a refractive index and an extinction coefficient of crystalline silicon (Si), amorphous silicon (a-Si), and polycrystalline silicon (Poly-Si). In FIG. 12, a section (a) illustrates a relationship between a refractive index and a wavelength of each material. A section (b) illustrates a relationship between an extinction coefficient k and a wavelength of each material, and a section (c) illustrates the vertical axis (extinction coefficient k) of the section (b) in an enlarged manner.

Preferably, α-Si has a large absorption with respect to light having a wavelength in the visible light region, but the same has no absorption with respect to light having a wavelength in the infrared region with the extinction coefficient k of approximately 0. Although polycrystalline silicon has a wavelength region with the extinction coefficient k of about 0.01 in the infrared region, the same has extremely small absorption and can be used as a lens as well.

According to the theoretical calculation by the Fraunhofer diffraction equation shown by the above-described Equation (3), the beam waist ω₀ decreases in inverse proportion as the refractive index n increases. Here, the refractive index n of silicon in the near infrared region is about n=3.4 to 3.8.

On the other hand, examples of a typical organic material generally used as a material of the on-chip lens 123a include a styrene-based resin, an acryl-based resin, a styrene-acrylic copolymer-based resin, a siloxane-based resin, and the like. These organic materials generally have a refractive index n of about n=1.45 to 1.6. Alternatively, the refractive index n of a typical inorganic material used as an on-chip lens material is n=about 1.8 to 1.9 for a silicon nitride film (SiN) and n=about 1.45 for SiO₂.

The refractive index n of silicon is much higher than the refractive index n of these general materials of the on-chip lens 123a. Therefore, by using silicon (α-Si, Si, Poly-Si) as the material of the on-chip lens 123a, the beam waist ω₀ with respect to the incident light 30 can be narrowed down as compared with the beam waist ω₀ by the on-chip lens 123a using the general organic material and inorganic material described above.

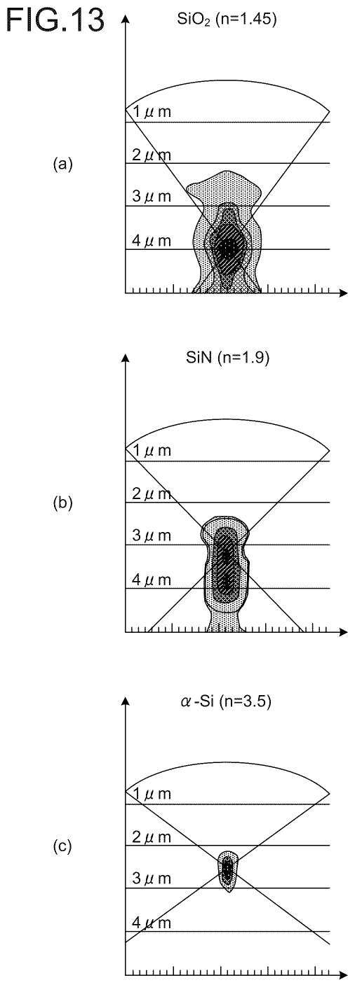

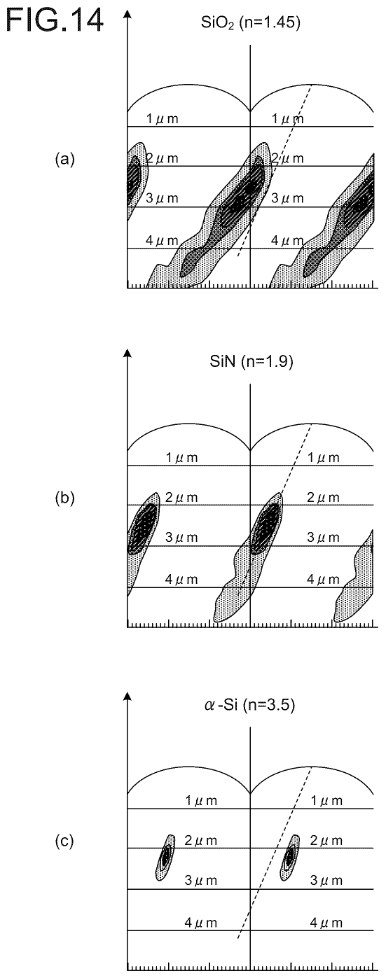

FIGS. 13 and 14 are schematic diagrams illustrating examples of a light intensity distributions of the on-chip lenses 123a having the same shape obtained by wave simulation. In FIGS. 13 and 14, the vertical axis represents the depth in the incident direction, and the horizontal axis represents the position in the width direction, respectively. In addition, in each drawing, the density of filling indicates the light intensity, and the darker the filling, the higher the light intensity.

Sections (a), (b), and (c) in FIGS. 13 and 14 illustrate examples of light intensity distributions in a case where the refractive indices n of the on-chip lenses 123a are n=1.45, n=1.9, and n=3.5, respectively. The sections (a) and (b) illustrate examples of light intensity distributions of SiO₂ and SiN, which are general inorganic materials, respectively. Furthermore, the section (c) illustrates an example of a light intensity distribution at a wavelength λ of 940 [nm] of silicon (a-Si) according to the first embodiment.

FIG. 13 is a diagram illustrating an example of refractive index dependency of a light condensing effect with respect to light at an incident angle of 0°. It can be seen that as the refractive index increases, the beam waist ω₀ of a light condensing point becomes narrower and narrower, and the light condensing point approaches the lens side. According to this effect, the pinhole 160 can be formed smaller, and the height of the light condensing structure can be reduced.

FIG. 14 is a diagram illustrating an example of the refractive index dependency of the light condensing effect with respect to obliquely incident light at an incident angle of 30°. Similarly to the example of FIG. 13, it can be seen that as the refractive index n of the on-chip lens 123a increases, the beam waist Wo of the light condensing point becomes narrower and narrower, and the light condensing point approaches the lens side. According to this effect, the pinhole 160 can be formed smaller, and the height of the light condensing structure can be reduced. Furthermore, in the image according to the Snell's law, the beam shift amount caused by oblique incidence is reduced. Since the responsiveness of the beam shift with respect to oblique incidence can be suppressed, the diameter of the pinhole 160 at the angle-of-view end can be further reduced with respect to F-value light of a module lens in which light of various angles is mixed.

The material of the on-chip lens 123a is preferably embedded in at least a part of the pinhole 160. By providing the pinhole 160 at the light condensing point of the on-chip lens 123a, it is possible to confine the light reflected or scattered by the reflection unit 151 provided on the surface on the opposite side of the light receiving surface of the photoelectric conversion unit 121 inside the photoelectric conversion unit 121 while suppressing the sensitivity loss of the incident light 30. As a result, it is possible to suppress the flare caused by the reflection component on the surface on the opposite side of the light receiving surface of the semiconductor substrate 140 described with reference to FIGS. 8 and 9.

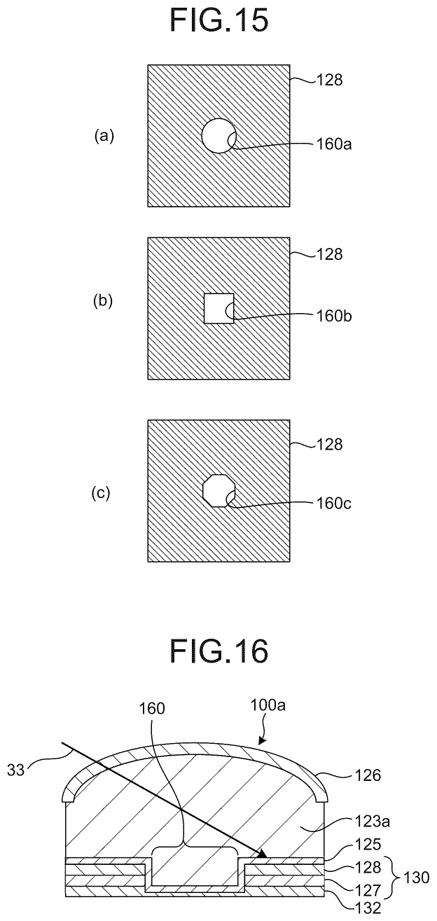

FIG. 15 is a schematic diagram illustrating an example of a basic shape of a pinhole applicable to the first embodiment. The pinhole 160 is a hole portion provided in the light shielding film 130, and is preferably adapted to the spread of the light intensity distribution and the two-dimensional shape at the height position of the light shielding film 130. A section (a) of FIG. 15 illustrates an example of a circular pinhole 160a, a section (b) of FIG. 15 illustrates an example of a rectangular (square) pinhole 160b, and a section (c) of FIG. 15 illustrates an example of an octagonal pinhole 160c, respectively. The shape of the pinhole 160 may be designed based on a light intensity distribution of a wave simulation or may be experimentally obtained. The shape of the pinhole 160 applicable to the first embodiment is not limited to the above-described circle, rectangle, and octagon.

The on-chip lens 123a may include the anti-reflection film 126 on the surface on the light receiving surface side and the anti-reflection film 125 on the surface on the semiconductor substrate 140 side. As the anti-reflection film for silicon, for example, SiN, titanium oxide (TiO₂), Al₂O₃, Ta₂O₃, or the like is preferably used.

The insulating film 132 is preferably provided between the light shielding film 130 and the semiconductor substrate 140 in the pixel, and the same has a large refractive index difference with respect to a high refractive index film forming the anti-reflection film 125, for example, the fixed charge film 141. Further, SiO₂ is typically used for the insulating film 132.

The element separating unit 124 is provided at a boundary portion between the pixel 100a and another pixel 100a adjacent to the pixel 100a, includes, for example, a p-type semiconductor region, and electrically separates the pixel 100a from the adjacent pixel 100a. By configuring the element separating unit 124 in this manner, it is possible to suppress a crosstalk phenomenon due to charge rolling.

Furthermore, as described with reference to FIG. 11A, a trench may be formed in a layout that surrounds and closes at least a part of the element separating unit 124, preferably the pixel 100a, and the fixed charge film 141 and the insulating film 132 may be embedded in the trench. By configuring the element separating unit 124 in this manner, it is possible to suppress optical crosstalk due to a reflection phenomenon caused by a refractive index difference with the semiconductor substrate 140 in addition to the charge rolling.

The wiring layer 150 transmits an image signal generated by the pixel 100a. Furthermore, the wiring layer 150 further transmits a signal applied to the pixel circuit. Specifically, the wiring layer 150 forms each signal line, each power supply line, and the like in FIG. 2. A connection via is provided between the wiring layer 150 and the pixel circuit, and the wiring layer 150 and the pixel circuit are connected by the connection via. Furthermore, the wiring layer 150 may be formed of multiple layers, and the layers of the respective wiring layers included in the wiring layer 150 are also connected by connection vias. The wiring layer 150 can be formed of, for example, a metal such as Al or Cu. The connection via can be formed of, for example, a metal such as W or Cu. For insulation of the wiring layer 150, for example, a silicon oxide film or the like can be used.

The reflection unit 151 is desirably provided on the surface on the opposite side of the light receiving surface of the semiconductor substrate 140. The reflection unit 151 reflects the incident light 30 transmitted through the photoelectric conversion unit 121 and causes the incident light to be incident on the photoelectric conversion unit again. As a result, the sensitivity of the photoelectric conversion unit 121 can be improved. The reflection unit 151 may also serve as a wiring of the wiring layer 150 and may be formed by arranging a large area pattern in a wiring layout. In this case, the large area pattern forming the reflection unit 151 preferably has an area ratio of at least 50 [%] or more, desirably 75 [%] or more, and more desirably 95 [%] or more in a region where the light intensity distribution exists when the multilayer wirings and the vias overlap each other in the wiring layer 150.

The support substrate 142 is a substrate that reinforces and supports the semiconductor substrate 140 and the like in the manufacturing process of the solid-state imaging device, and is formed of, for example, silicon. The support substrate 142 is bonded to the semiconductor substrate 140 by plasma bonding or an adhesive material to support the semiconductor substrate 140 and the like. In the support substrate 142, a logic circuit may be formed therein, and it is possible to reduce a chip size by vertically stacking various peripheral circuit functions by forming a connection via between substrates.

The diffractive/scattering structure 129 is provided at an end portion of the semiconductor substrate 140 on the light receiving surface side of the photoelectric conversion unit 121 in the pixel 100a. The diffractive/scattering structure 129 is formed by a moth-eye structure in which a periodic uneven structure is provided at an interface on the light receiving surface side of the semiconductor substrate 140 having the photoelectric conversion unit 121 formed thereon.

The moth-eye structure has an anti-reflection effect by making a difference in refractive index gentle at the light incident interface of the substrate. Further, the moth-eye structure also functions as a light diffraction unit that diffracts light with the uneven structure. Specifically, as the diffractive/scattering structure 129, for example, a quadrangular pyramid formed by using wet etching of a Si (111) surface can be applied. The present disclosure is not limited thereto, and the diffractive/scattering structure 129 may be formed by dry etching.

In this manner, by providing the pinhole 160 at the light condensing point of the on-chip lens 123a, it is possible to confine the light reflected or scattered by the reflection unit 151 provided on the surface on the opposite side of the light receiving surface of the photoelectric conversion unit 121 in the photoelectric conversion unit 121 while suppressing the sensitivity loss with respect to the incident light 30. Accordingly, it is possible to suppress occurrence of a flare or the like caused by reflection of the incident light 30 by the surface on the opposite side of the light receiving surface of the photoelectric conversion unit 121 described with reference to FIGS. 7 and 8.

Furthermore, a part of the incident light 30 is incident into the photoelectric conversion unit 121 as 0th-order light in the pixel 100a, and the optical path of the other part of the incident light 30 is changed by the diffractive/scattering structure 129. Thereafter, the other part of the incident light 30 is incident into the photoelectric conversion unit 121 as first-order light. Further, the part of the light incident on the photoelectric conversion unit 121 is reflected by the reflection unit 151, and light transmitted through the diffractive/scattering structure 129 as intra-element reflected light 202 reaches a reflection film 127. The intra-element reflected light 202 is reflected by the reflection film 127, and the optical path thereof is changed by the diffractive/scattering structure 129. Thereafter, the same is incident into the photoelectric conversion unit 121. At this time, emission of light in the photoelectric conversion unit 121 to the outside of the photoelectric conversion unit 121 is suppressed by the reflection film 127 having the pinhole 160.

As described above, in the pixel 100a according to the first embodiment, the optical path of the incident light 30 in the photoelectric conversion unit 121 can be made long by the reflection unit 151, the reflection film 127, and the diffractive/scattering structure 129, and the photoelectric conversion efficiency in the photoelectric conversion unit 121 can be enhanced.

Furthermore, the light shielding film 130 having the pinhole 160 provided therein can provide a removal effect for unnecessary light. FIG. 16 is a schematic diagram illustrating how a removal effect for unnecessary light is obtained by the light shielding film 130 provided with the pinhole 160 according to the first embodiment. As illustrated in FIG. 16, the external light 33, which is external stray light incident on the pixel 100a, is blocked by the light shielding film 130, and the same is suppressed from being incident on the photoelectric conversion unit 121. Furthermore, emission of the external light 33 to the outside as reflected light is also suppressed by the anti-reflection film 125.

(4-0-2. Example of Manufacturing Method of Pixel According to First Embodiment)

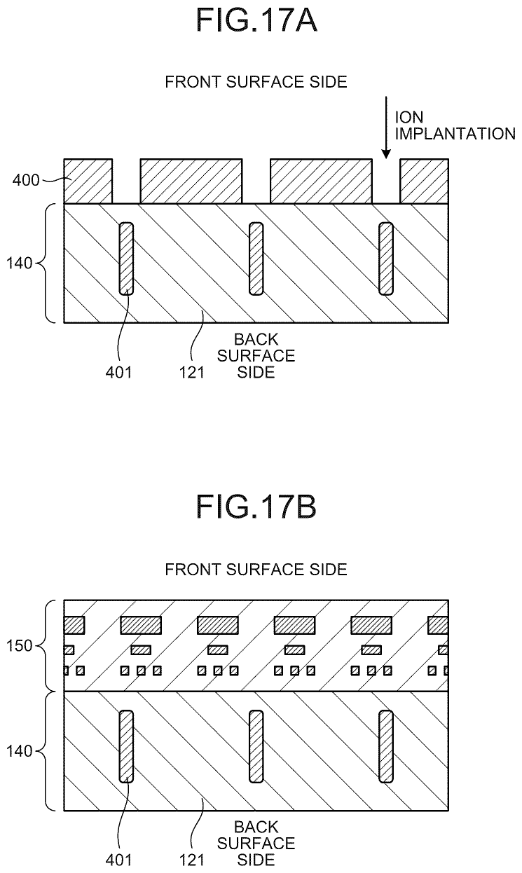

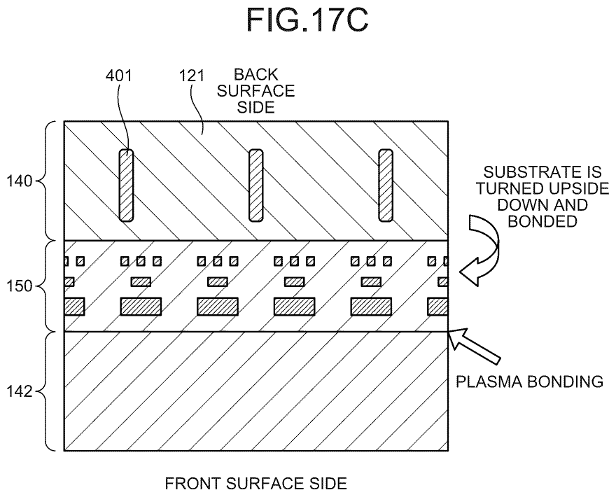

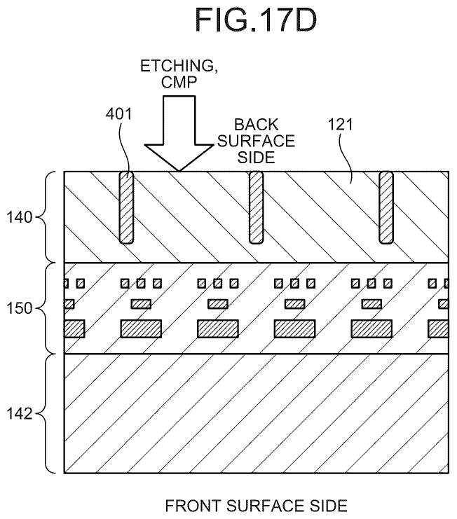

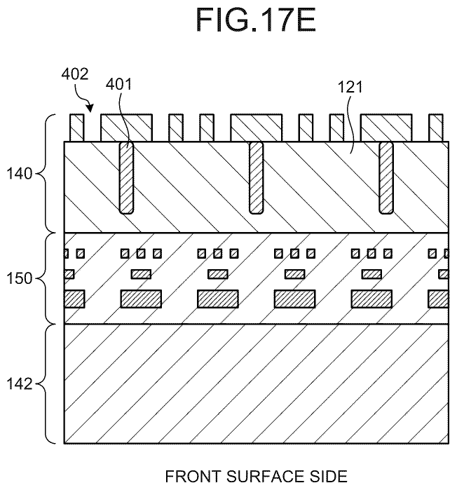

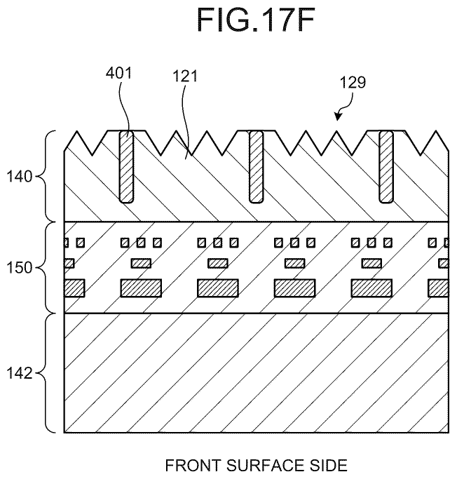

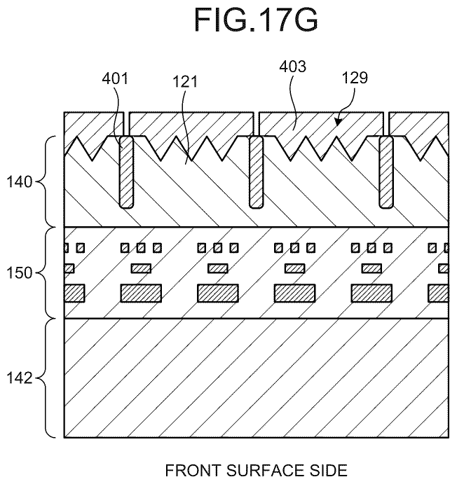

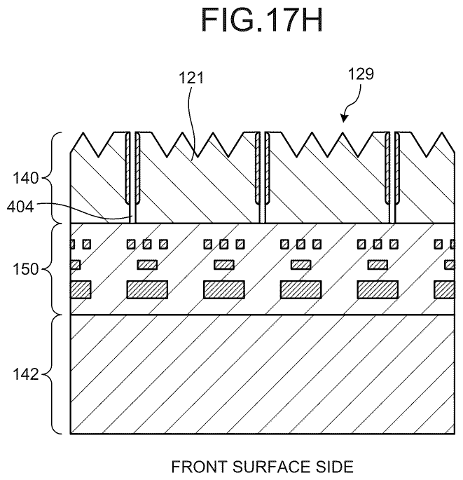

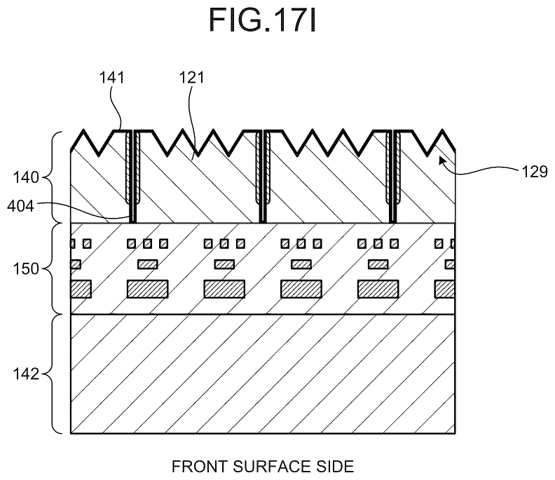

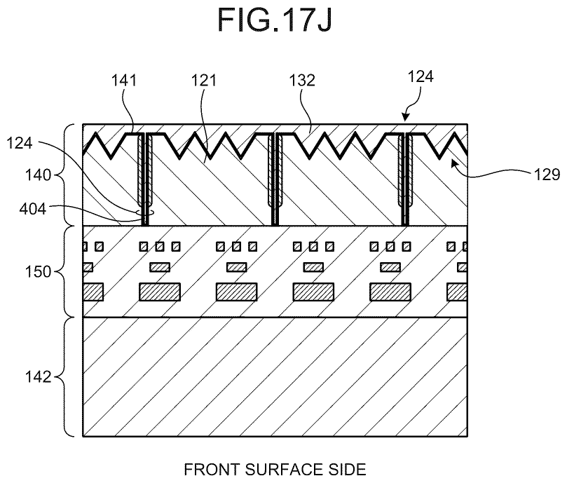

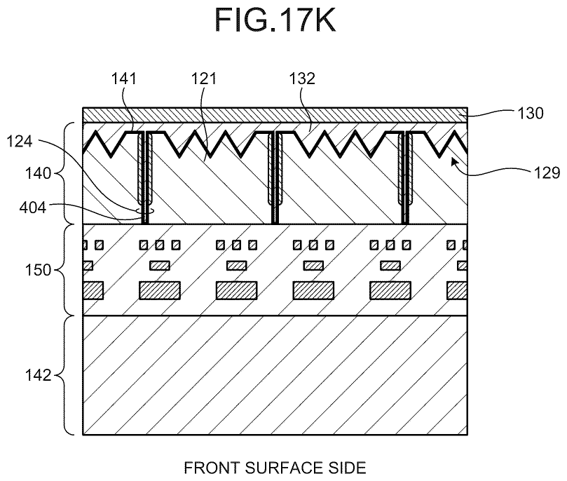

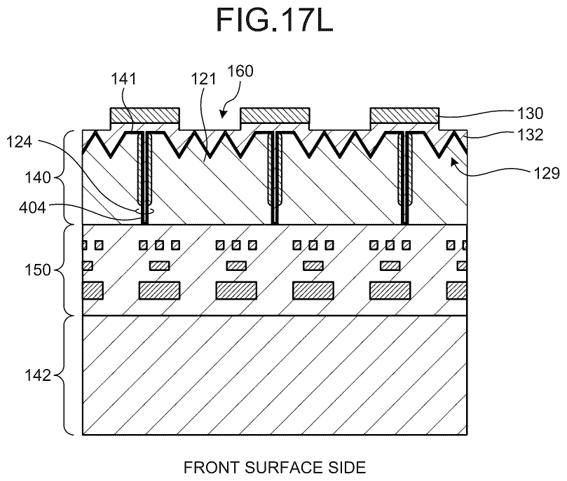

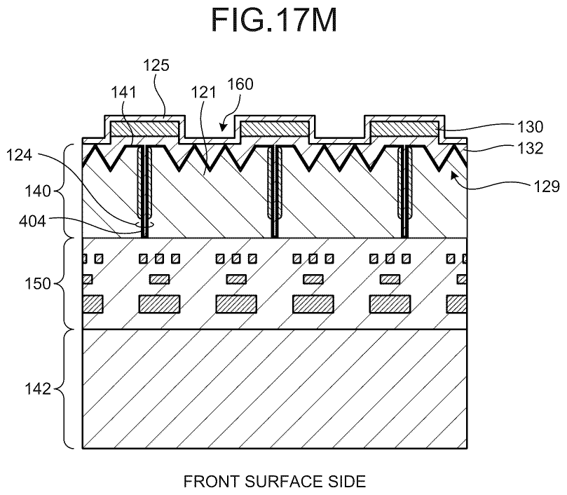

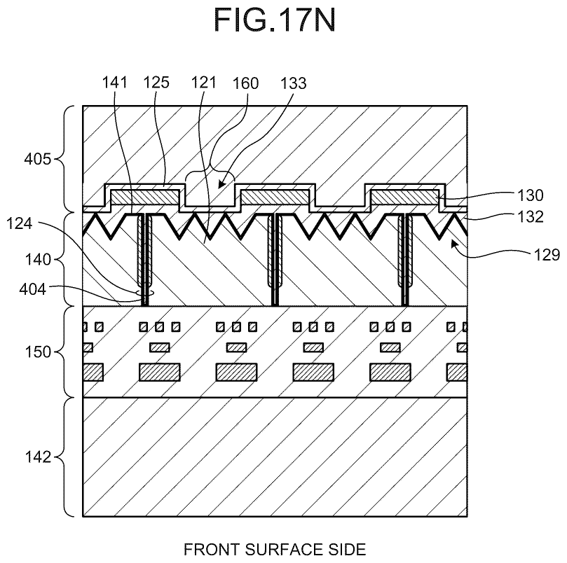

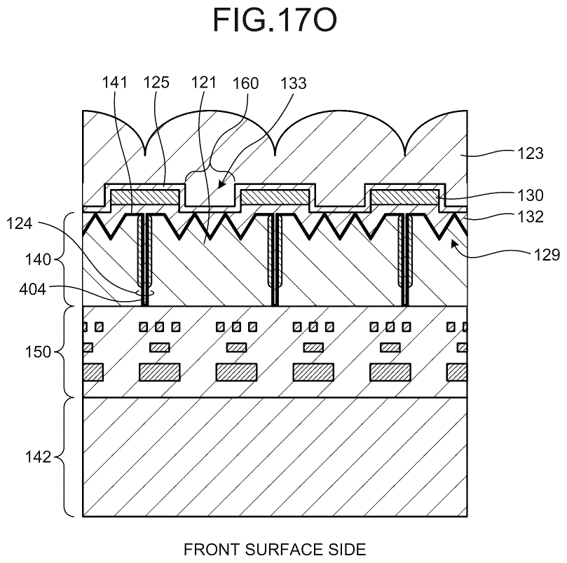

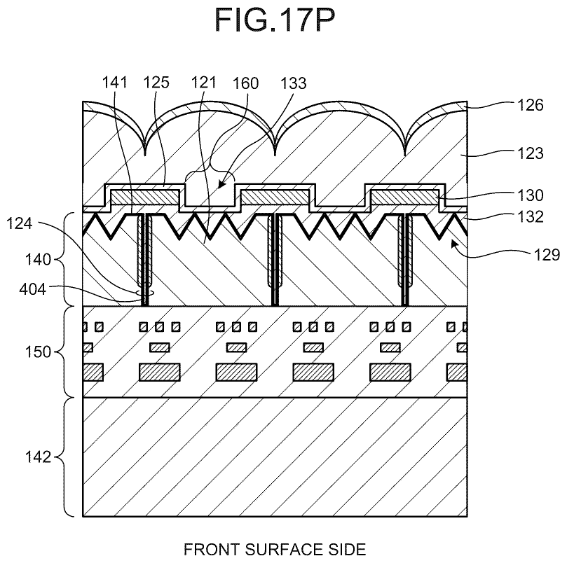

Next, a manufacturing method of an example of the pixel 100a according to the first embodiment will be described with reference to FIGS. 17A to 17P.

For example, a pattern is formed with a resist on the front surface side of the semiconductor substrate 140, which is a silicon substrate, a p-type well region 401, an n-type semiconductor region, and the like are formed on the semiconductor substrate 140, and the photoelectric conversion unit 121 and the like are formed by ion implantation (FIG. 17A).

The wiring layer 150 including a plurality of MOS transistors 103 configured to read out charges accumulated in a photodiode and a plurality of layers formed of Al, Cu, or the like with an interlayer insulating film such as an SiO₂ film interposed therebetween is formed on the upper portion of the substrate surface (FIG. 17B).

Among the plurality of layers included in the wiring layer 150, a layer closest to the semiconductor substrate 140 may be designed with a large area pattern having an area ratio of 50% or more to form the reflection unit 151. A through via is formed between the substrate surface and the wiring layer 150, and is electrically connected to drive an imaging element. A wiring is generally designed three-dimensionally in multiple layers, and an interlayer insulating film such as a SiO₂ film is laminated on the wiring, the surface of a wiring layer is made to be a substantially flat surface by chemical mechanical polishing (CMP), an upper layer wiring is formed thereon, the upper layer wiring is connected to a lower layer wiring by a through via repeatedly, and the wiring having the designed number of layers is sequentially formed.

The substrate is turned upside down and bonded to the support substrate 142 by plasma bonding or the like (FIG. 17C), and the back surface is ground using, for example, wet etching, dry etching, CMP or the like to be thinned (FIG. 17D).

Next, a description will be given as to a process of forming, for example, a moth-eye structure having periodic quadrangular pyramidal unevenness as the diffractive/scattering structure 129 on the light receiving surface side of the semiconductor substrate 140. On the surface of the Si layer, a resist mask is formed on the convex portion of the uneven pattern in the lithography process (FIG. 17E), a concave portion is formed by anisotropic etching of crystallinity by wet etching, and the resist is removed (FIG. 17F). When the concave portion of the uneven pattern is formed, the light receiving surface and the opposite surface of the Si layer are the crystal plane (100) surface, and the wall surface of the concave portion is the crystal plane (111) surface, so that it is possible to form a highly accurate quadrangular pyramidal uneven pattern while suppressing crystal defects by anisotropic etching of crystallinity.

Next, a description will be given as to a process of forming a trench structure in which the fixed charge film 141 and the insulating film 132 are embedded as the element separating unit 124 on the light receiving surface side of the semiconductor substrate 140. On the surface of the Si layer, the photoelectric conversion unit 121 is covered with a resist 403 in the lithography process (FIG. 17G), and a resist mask is formed so that a portion corresponding to each pixel boundary is opened in a lattice shape. Trench processing is performed by etching through the resist mask. In order to achieve etching with a high aspect ratio, dry etching such as a Bosch process in which protection of the etching side surface and etching are repeatedly performed is preferable.

Next, a resist and a residue are removed by ashing, chemical cleaning, or the like (FIG. 17H). A trench 404 is formed according to the pattern of the resist mask.

Next, the fixed charge film 141 and the insulating film 132 are sequentially formed on the light receiving surface of the semiconductor substrate including the unevenness of the diffractive/scattering structure 129 and inside the trench (FIG. 17I, FIG. 17J). As a film forming method, chemical vapor deposition (CVD), atomic layer deposition (ALD), sputtering, or the like can be used. The surface of the insulating film 132 may be planarized by CMP. Here, an example in which the diffractive/scattering structure 129 is processed on the receiving surface side has been described, but the present disclosure is not limited thereto, and the diffractive/scattering structure 129 may be processed by a similar manufacturing method from the wiring layer side.

When the trench 404 is formed in the element separating unit 124, it is desirable to form the semiconductor substrate 140 deeply in the thickness direction from the viewpoint of suppressing the crosstalk, and it is more desirable to have a full trench structure penetrating therethrough. However, deepening the trench 404 may cause deterioration of characteristics in the dark due to processing damage, and it is desirable that the element separating unit 124 reinforces pinning by forming the fixed charge film 141 on the side wall portion or the bottom portion, or by increasing impurity concentration in the semiconductor substrate.

Next, a part of the insulating film 132 is subjected to trench processing (not illustrated) by lithography and dry etching so that the surface of the semiconductor substrate 140, which is a p-type semiconductor region, is exposed in any of the regions outside the effective pixels, and a metal film, for example, W or Al is formed as the light shielding film 130 by CVD, sputtering, or the like (FIG. 17K). It is noted that the trench processing here is performed to set the light shielding film 130 to the ground potential, and thereby plasma damage generated during processing can be avoided.

The film thickness of the light shielding film 130 is desirably thick from the viewpoint of a light shielding property, is desirably thin from the viewpoint of suppressing vignetting of the pinhole 160 and facilitating processing, and is desirably about 50 to 300 [nm] and preferably 100 to 250 [nm] in terms of a balance between the both viewpoints. As a measure against adhesion improvement and stress migration, a barrier metal such as Ti or TiN of about 10 to 50 [nm] may be formed under the light shielding film 130.

Next, a resist mask with a pinhole portion opened is formed on the light shielding film 130 by lithography, the pinhole 160 is formed by using etching such as dry etching, and the resist and the residue are removed by ashing, chemical cleaning, or the like (FIG. 17L). In the etching, not only the light shielding film 130 but also the insulating film 132 in an opening portion is desirably etched by at least 50 [nm], and if possible, by 100 [nm] or more. Since the lower surface of silicon of the lens material embedded in a hole portion to be described later is located closer to the side of the photoelectric conversion unit 121 than the light shielding film 130, confinement effect by the light shielding film 130 can be enhanced.

Next, as the anti-reflection film 125 for the lower surface of the on-chip lens, for example, a film of SiN may be formed by ALD, CVD, sputtering, or the like (FIG. 17M). If ALD or CVD is used, it is possible to uniformly form a film including the side wall portion, and if sputtering is used, a film can be formed only on a flat portion and a bottom of the hole. The film thickness of the anti-reflection film 125 is desirably designed to be anti-reflective in consideration of an assumed wavelength, and here, SiN is set to 100 to 150 [nm] with respect to a wavelength of 940 [nm].

When the anti-reflection film 125 is provided, it is desirable to increase the over-etching amount of the insulating film 132 by the film thickness of the anti-reflection film 125 described above. However, if the surfaces of the fixed charge film 141 and the Si layer are etched due to process variations, there is a concern that the characteristics in the dark may deteriorate due to processing damage, and as such, it is desirable to increase the initial film thickness of the insulating film 132 as necessary.

Next, as a lens material 405 of the on-chip lens 123, for example, a film of α-Si is formed at the temperature of about 200 to 400° C. by a method such as CVD or sputtering (FIG. 17N). If a void (air layer) is generated in the hole portion when α-Si is embedded in the pinhole 160, transmittance decreases, and thus CVD that is less likely to close the hole portion is suitable. α-Si has an advantage that it is easy to form a film on a non-crystalline material or a material that cannot withstand high temperatures.

Alternatively, polysilicon may be used as the lens material 405. Since polysilicon requires a film formation temperature of 600 to 1000° C., polysilicon is not suitable for a process after the formation of the wiring layer 150, but the film formation of polysilicon can be performed at the temperature of 400° C. or lower by laser annealing or utilizing excitation energy of an ion beam. When hydrogen of α-Si is desorbed in the high temperature standing of the reliability test and does not satisfy the characteristics to be guaranteed, it is desirable to use polysilicon in a stable crystalline state.

If the above-described anti-reflection film 125 is also formed on the side wall of the pinhole 160 by CVD or the like, the inside serves as a core portion made of silicon having a high refractive index, and the outside serves as a cladding portion made of the anti-reflection film 125 having a low refractive index, so that the optical waveguide 133 can be formed inside the pinhole. In the optical waveguide 133 provided inside the pinhole 160, it is desirable that the lower surface of the optical waveguide 133 protrudes from the lower surface of the light shielding film 130 and extends toward the side of the photoelectric conversion unit 121.

On the silicon of the lens material 405, for example, a resist is patterned and developed by a lithography process so as to remain in a rectangular shape in each pixel. Thereafter, heat treatment is performed at a temperature higher than a heat softening point to form the resist in a lens shape. Then, using the resist having a lens shape as a mask, the lens shape is transferred to the underlying silicon by dry etching using, for example, CF₄/O₂, C₄F₈, or the like (FIG. 17O).

In order to improve the adhesion between silicon of the lens material 405 and the base, the surface may be roughened with plasma such as He, Ar, O₂, or N₂ before film formation. When it is necessary to more firmly increase the adhesion with the base, a film of a silane coupling agent may be formed by spin coating or CVD. These film forming methods can be applied to various underlayers such as inorganic materials such as the insulating film 132, the fixed charge film 141, and the anti-reflection film 125, or an organic material such as a color filter.

The silane coupling agent has two or more different reactive groups in the molecule, one is a reactive group chemically bonded to the inorganic material, and the other is a reactive group chemically bonded to the organic material. Therefore, the silane coupling agent has a function as an intermediary that connects the organic material to the inorganic material, which are usually very difficult to be bonded to each other. As the silane coupling agent, an alkoxysilane having any organic group can be used, and examples of the organic group include an alkyl group, an epoxy group-containing group, an amino group-containing group, a mercapto group-containing group, a (meth) acrylic group-containing group, a polymerizable double bond-containing group, and an aryl group.

As the anti-reflection film 126, for example, a film of SiN may be formed on the on-chip lens 123 by ALD, CVD, sputtering, or the like (FIG. 17P). The film thickness of the anti-reflection film 125 is desirably designed to be anti-reflective in consideration of an assumed wavelength, and here, SiN is set to 100 to 150 [nm] with respect to a wavelength of 940 [nm].

(4-0-3. More Detailed Description of Pixel According to First Embodiment)

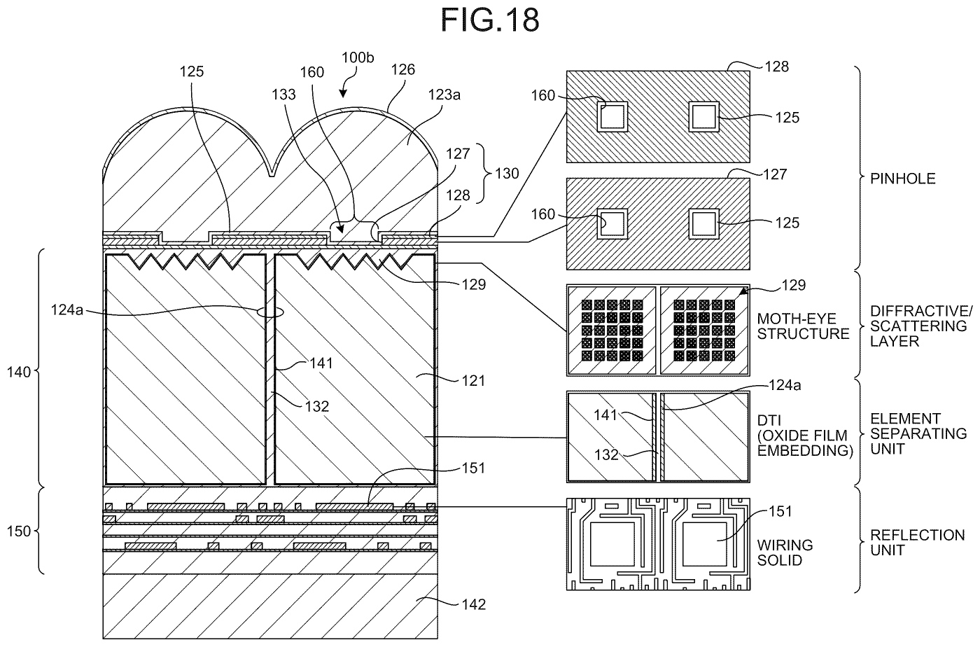

Next, the pixel 100a according to the first embodiment will be described in more detail. FIG. 18 is a schematic diagram illustrating a structure example of the pixel 100a according to the first embodiment in more detail. In FIG. 18, the diagram on the left side is a schematic diagram illustrating a cross section of the pixel 100a in the direction perpendicular to the light receiving surface. Furthermore, the diagram on the right side is a schematic diagram illustrating a state in which each unit of the pixel 100a is viewed from the incident side of the incident light 30.

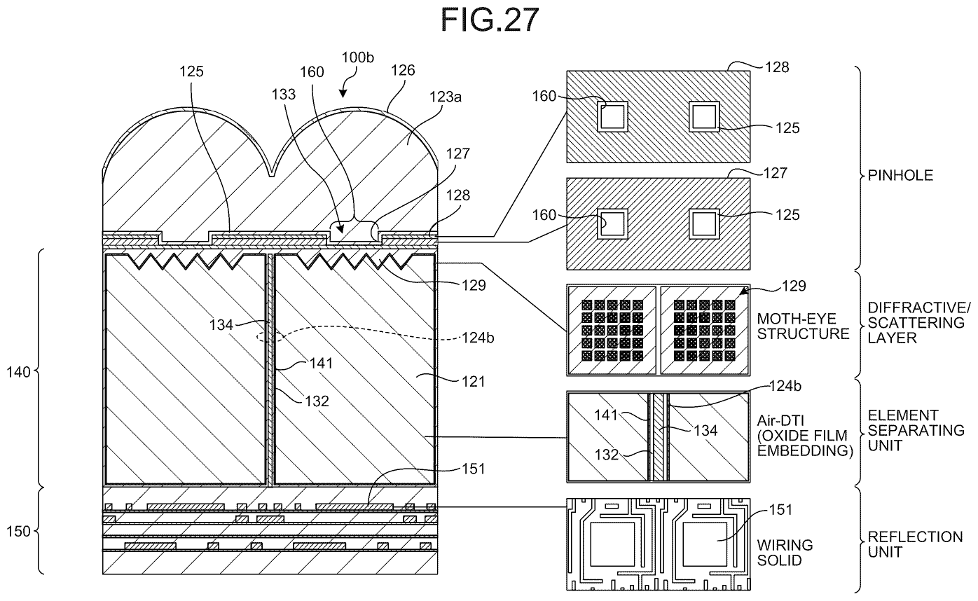

It is noted that the meanings of these left and right diagrams in FIG. 18 are the same in the following similar diagrams (FIGS. 27 to 30, FIGS. 32 to 37). Furthermore, in the following description, unless otherwise specified, the upper side is described as the upper side of the pixel 100 and the lower side is described as the lower side of the pixel 100 in FIGS. 27 to 30 and FIGS. 32 to 37. Furthermore, the incident surface side of the photoelectric conversion unit 121 is appropriately referred to as a top of the photoelectric conversion unit 121, and the opposite side of the incident surface is appropriately referred to as a bottom of the photoelectric conversion unit 121. Furthermore, in FIGS. 18, 27 to 30, and 32 to 37, illustration of an optical filter such as a color filter is omitted.

In the configuration illustrated in FIG. 18, the film thicknesses of each of the anti-reflection film 126 on the lens, the anti-reflection film 125 under the lens, and the fixed charge film for Si is approximately designed in accordance with the λ/4 rule. As a specific example, in a case where the wavelength λ=940 [nm] and the incident angle is 0°, for example, each film thickness is described as follows.
SiN film (n=1.88): about 110 to 140 [nm]
TiO₂ film (n=2.4): about 90 to 110 [nm]

At this time, it is preferable to further consider the angular influence and the multilayer influence in the Fresnel coefficient. The actual structure of the pixel 100 has a multilayer film configuration formed on the semiconductor substrate 140, and it is desirable to set the optimum film thickness in consideration of the entire structure. Furthermore, since the incident angle of light from the main lens also varies depending on the angle of view, it is more desirable to obtain an optimum value in consideration of angle dependency.

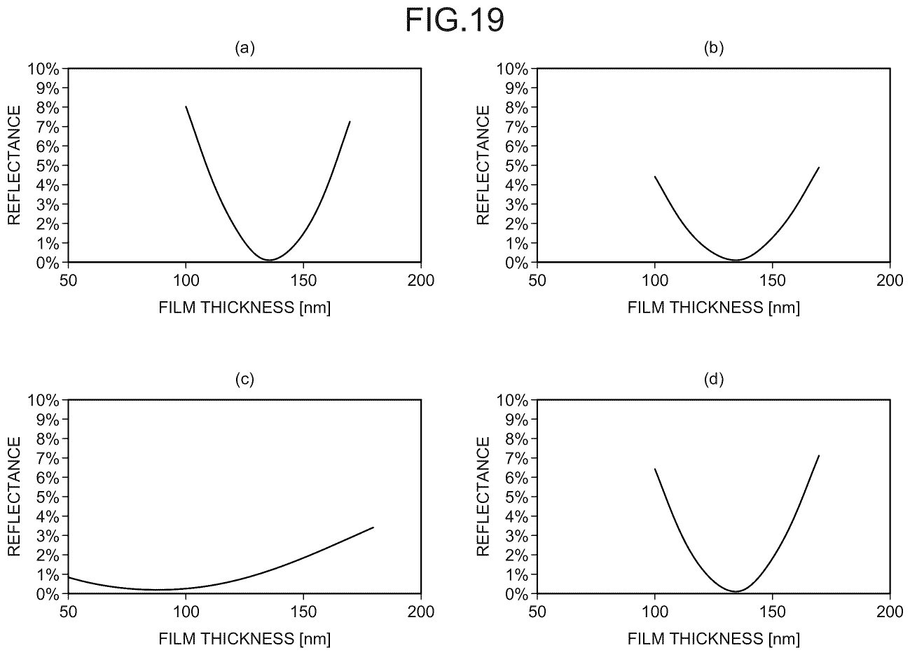

With reference to FIGS. 19, 20, and 21, a description will be given as to a calculation result when optimization is performed according to theoretical calculation of the Fresnel coefficient for the first embodiment. It is noted that, in the following description, it is assumed that each layer is formed in the order of Al₂O₃, Ta₂O₅, SiO₂, SiN (referred to as first SiN), α-Si (on-chip lens 123a), and SiN (referred to as second SiN) from the side closer to the light receiving surface of the semiconductor substrate 140.

FIG. 19 is a diagram illustrating a simulation result of film thickness dependency of reflectance of each layer at the wavelength λ=940 [nm]. In FIG. 19, a section (a) illustrates the film thickness dependency of the reflectance of the second SiN, a section (b) illustrates the film thickness dependency of the reflectance of the first SiN, a section (c) illustrates the film thickness dependency of the reflectance of SiO₂, and a section (d) illustrates the film thickness dependency of the reflectance of Ta₂O₅.

It is noted that the thickness of α-Si of the on-chip lens 123a is assumed to be 1000 [nm] here because the optimum value of light condensation varies with respect to the pixel size. Al₂O₃ used for the lower layer of the fixed charge film 141 is determined by balance between the role of pinning and the throughput of ALD film formation, and is set to 15 [nm] here.

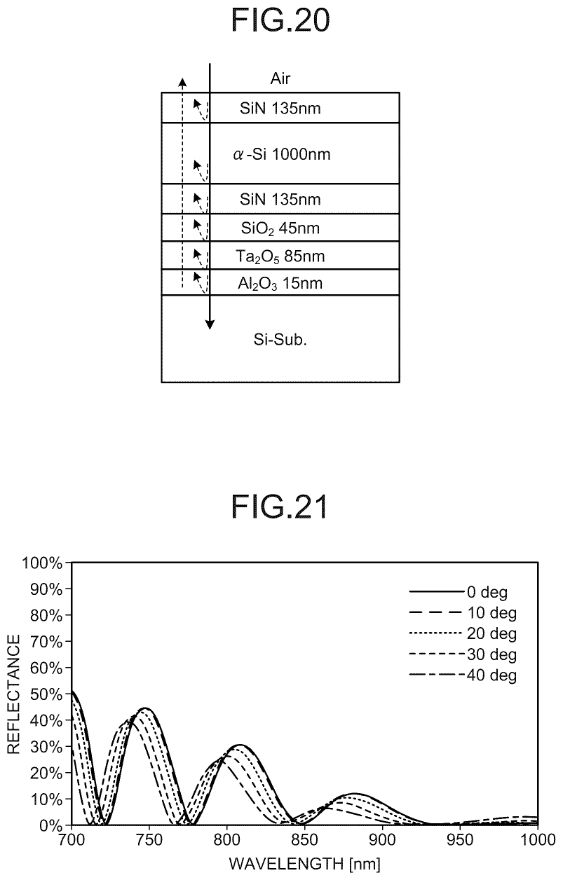

FIG. 20 is a diagram illustrating an example of an optimal structure obtained as a result of performing anti-reflection design on the above-described assumption. According to FIG. 20, in order from the incident surface side, the film thickness of each of the anti-reflection film 126 on the lens and the anti-reflection film 125 under the lens is 135 [nm] in a case where SiN is used, the film thickness of the insulating film 132 is 45 [nm] in a case where SiO₂ is used, and the film thickness of the fixed charge film 141 using Ta₂O₅ is about 85 [nm] on the film thickness of 15 [nm] of Al₂O₃.

FIG. 21 is a diagram illustrating a simulation result of the reflection spectrum in the configuration of FIG. 20. As illustrated in FIG. 21, according to the configuration of FIG. 20, the reflectance is less than 1 [%] at the wavelength λ=940 [nm], and the optical characteristics can be maintained up to the incident angle of 30°.

In addition, since there is a loss in reflection at the bottom of the photoelectric conversion unit 121, the thickness of the Si layer of the semiconductor substrate 140 is preferably 4 [μm] or more in consideration of quantum efficiency. The upper limit of the thickness of the Si layer of the semiconductor substrate 140 is desirably set to at least 18 [am] or less, and more preferably 14 [μm] in consideration of energy restriction of an implantation device, variations in DTI processing in the element separating unit 124a, and the like. However, the upper limit of the thickness of the Si layer of the semiconductor substrate 140 is not limited thereto, because the upper limit is affected by characteristics of a device related to manufacturing.

In such a configuration, the incident light 30 is narrowed by the on-chip lens 123a, and the optical path length of the incident light 30 is extended by the diffractive/scattering structure 129 after the incident light 30 passes through the pinhole 160. Furthermore, the oblique light is reflected by the element separating unit 124a having a DTI structure, and the same is returned to the inside of the photoelectric conversion unit 121 as the intra-element reflected light 202. Furthermore, at the bottom of the photoelectric conversion unit 121, the incident light 30 is reflected by the reflection unit 151 and returned to the inside of the photoelectric conversion unit 121 as the intra-element reflected light 202.

Further, the emission port of the intra-element reflected light 202 directed to the upper portion of the photoelectric conversion unit 121 is limited by the pinhole 160, and the intra-element reflected light 202 is returned to the inside of the photoelectric conversion unit 121 by the reflection film 127 provided with the pinhole 160.

As described above, the pixel 100a according to the first embodiment can efficiently confine the incident light 30 in the photoelectric conversion unit 121, and can achieve both high sensitivity and suppression of a flare caused by the reflected light reflected by the wiring layer 150. Furthermore, as described with reference to FIG. 16, the pinhole 160 is provided, thereby making it possible to suppress a flare caused by the external light 33, which is external stray light. Furthermore, the upper surface side on which the pinhole 160 is formed is used as an anti-reflection film 128, thereby also suppressing the reflected light from being emitted to the outside.

(4-1. Modification of Pinhole Applicable to First Embodiment)

Next, the pinhole 160 applicable to the first embodiment will be described more specifically.

(Shape of Pinhole)

Each shape (circular, rectangular, octagonal) of the pinholes 160a, 160b, and 160c illustrated in FIG. 15 described above is a basic shape, and the shape of the pinhole 160 can be changed according to, for example, the light intensity distribution in the effective pixel region of the pixel 100a.

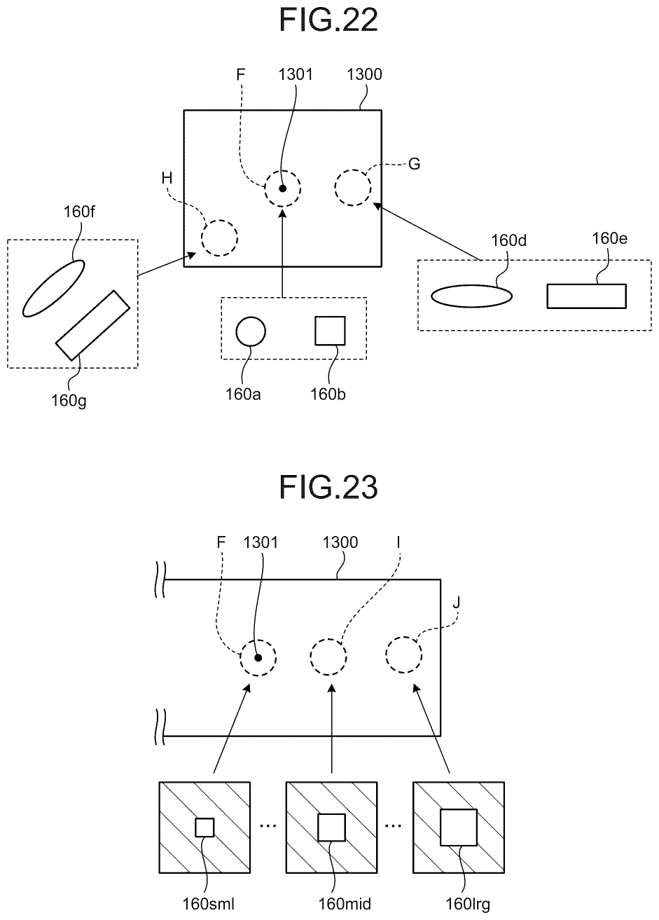

FIG. 22 is a schematic diagram illustrating an example in which the shape of the pinhole 160 is changed within the angle of view according to the assumed light intensity distribution of the first embodiment. In FIG. 22, an effective pixel region 1300 is a region including the pixel 100 used to form an image of one frame, and is a region corresponding to an angle of view. In the example of FIG. 22, a center position 1301 of the effective pixel region 1300 is the image height center at which the position of the optical axis of the main lens in the optical unit 11 and the center position 1301 coincide with each other.

In a range F including the center position 1301, for example, the light intensity distribution has a substantially circular shape or a substantially rectangular shape. The pinhole 160a or the pinhole 160b having the basic shape illustrated in FIG. 15 can be applied to this range F as the pinhole 160. The octagonal pinhole 160c is also applicable to the range F, but the illustration thereof is omitted in FIG. 22.

At a position shifted toward the peripheral direction of the angle of view with respect to the center position 1301 of the angle of view, the light intensity distribution has a shape conforming to an elliptical shape in which the direction from the center position 1301 is set as the major axis direction, and the ratio of the major axis to the minor axis is a value corresponding to a distance. In order to allow more incident light 30 to be incident on the photoelectric conversion unit 121 in accordance with the angle-of-view dependency of the light intensity distribution, the shape of the pinhole 160 is changed depending on the position of the pixel 100a within the angle of view.

For example, in a range G shifted from the center position 1301 in the horizontal direction of the angle of view (effective pixel region 1300), the shape of the pinhole 160 can be a shape in which the pinhole 160a or 160b in the range F is extended in the horizontal direction as illustrated in a pinhole 160d or a pinhole 160e. In addition, for example, in a range H shifted from the center position 1301 in the angular direction of the angle of view, the shape of the pinhole 160 can be a shape in which the pinhole 160a or 160b in the range F is extended in the angular direction as illustrated in a pinhole 160f or a pinhole 160g.

Furthermore, the size of the pinhole 160 can be changed according to the light intensity distribution within the angle of view (effective pixel region 1300). FIG. 23 is a schematic diagram illustrating an example in which the size of the pinhole 160 is changed within the angle of view according to the assumed light intensity distribution of the first embodiment.

The spread of the distribution of the light intensity within the angle of view changes from the optical axis position, that is, the center position 1301 of the angle of view toward the periphery. Therefore, in order to allow more incident light 30 to be incident on the photoelectric conversion unit 121, the size of the pinhole 160 is continuously changed depending on the distance from the center position 1301. In the example of FIG. 23, the pinhole 160 is a pinhole 160mid larger than a pinhole 160sml in a local range I away from the center position 1301 with respect to the pinhole 160sml in the local range F including the center position 1301. In a range J further away from the center position 1301 with respect to the range I, a pinhole 160lrg is larger than the pinhole 160mid.

(Pupil Correction)

Next, pupil correction according to the first embodiment will be described. Within the angle of view, the angle of the principal ray with respect to the pixel 100a and the shape of the exit pupil change according to the image height of each pixel 100a with respect to the optical axis position of the main lens. Therefore, there is known a pupil correction technology of efficiently guiding light from the main lens to the photoelectric conversion unit 121 by shifting the position of the on-chip lens 123a or the like of each pixel 100a according to the image height and the height in the light condensing structure.

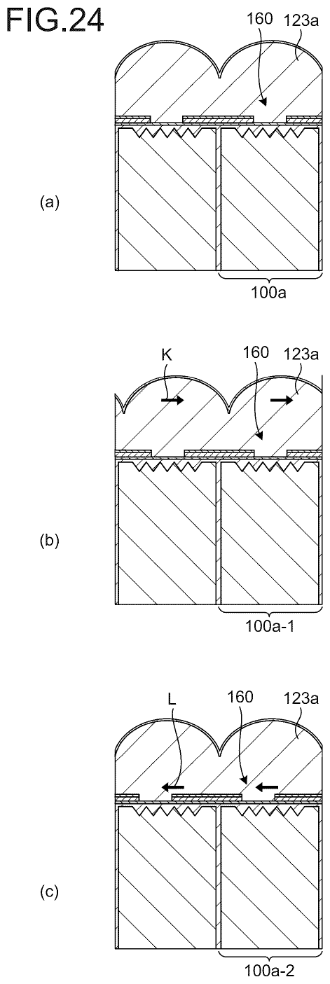

FIG. 24 is a schematic diagram illustrating a pupil correction method according to the first embodiment in comparison with a pupil correction method according to the existing technology. It is noted that, in FIG. 24, the configuration of an example of the pixel 100a is illustrated by a cross section in the direction perpendicular to the light receiving surface.

In FIG. 24, a section (a) illustrates a state in which pupil correction is not performed. In this state, the position of the vertex of the on-chip lens 123a and the position of the pinhole 160 coincide with the center of the light receiving surface in the pixel 100a.

A section (b) of FIG. 24 is a diagram illustrating the pupil correction according to the existing technology. In the existing technology, the pupil correction is executed by moving the position of the on-chip lens 123a in a pixel 100a-1, as indicated by an arrow K. In the first embodiment, as indicated by an arrow L in a section (c) of FIG. 24, the pupil correction can also be performed by moving the pinhole 160 without moving the on-chip lens 123a in a pixel 100a-2. Since the pupil correction by movement of the on-chip lens 123 has interference with an adjacent lens, it is difficult to significantly differ the pupil correction amount from the neighboring pixels, whereas the design of the pinhole 160 enables pupil correction different for each pixel 100a-2. It is noted that it is also possible to apply pupil correction of the on-chip lens 123 and pupil correction of the pinhole 160 in combination.

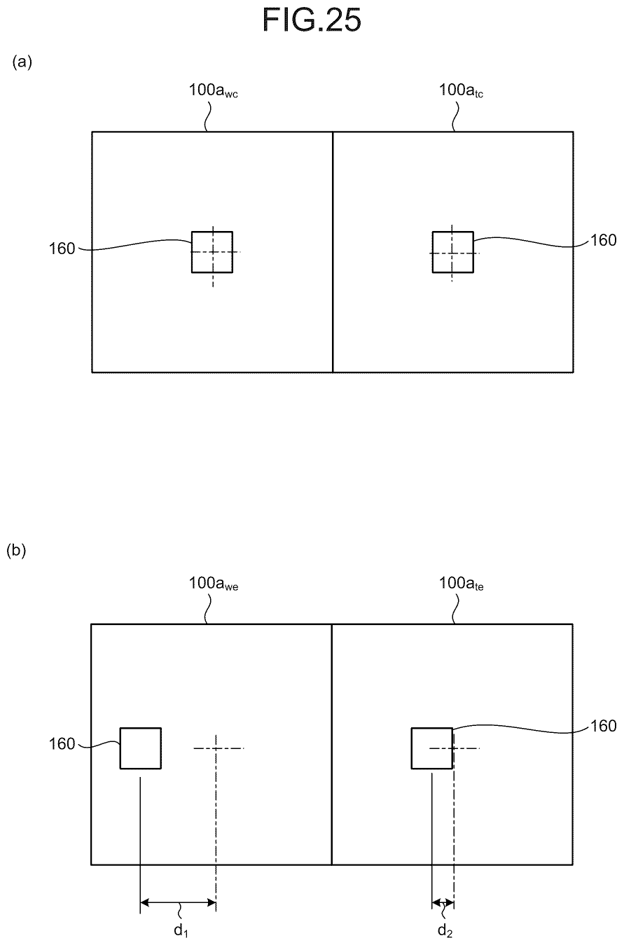

FIG. 25 is a schematic diagram illustrating an application example of the pupil correction according to the first embodiment. The example of FIG. 25 is an example in which the pinhole 160 is made different between a pixel for wide image capturing in which the inclination of the principal ray increases at the angle-of-view end and an image for telephoto image capturing in which the principal ray approaches parallel.

A section (a) of FIG. 25 illustrates a pixel 100a_{we} for wide image capturing and a pixel 100a_{tc} for telephoto image capturing in the central portion of the angle of view. In the pixels 100a_{wc} and 100a_{tc}, the pinhole 160 is provided in each of the central portions.

A section (b) of FIG. 25 illustrates, for example, a pixel 100a_{we} for wide image capturing and a pixel 100aₜₑ for telephoto image capturing at the left end portion of the angle of view in the horizontal direction. In the pixel 100aₜₑ, the pinhole 160 is provided to be shifted to the left by a distance da from the center of the pixel 100aₜₑ. On the other hand, in the pixel 100a_{we}, the pinhole 160 is provided to be shifted to the left from the center of the pixel 100a_{we} by a distance d₁ larger than the distance d₂.

It is noted that the pixels 100a_{wc} and 100a_{we} for wide image capturing and the pixels 100a_{tc} and 100aₜₑ for telephoto image capturing can be mixed and alternately disposed, for example, in the angle of view. For example, in a case where the optical unit 11 is compatible with a lens exchange method or a zoom mechanism, it is possible to switch which one of the pixels 100a_{wc} and 100a_{we} for wide image capturing and the pixels 100a_{tc} and 100aₜₑ for telephoto image capturing is used depending on the change in angle of view or zoom magnification.

(Regarding Size of Pinhole)

Here, the size of the pinhole 160 will be described. As described above, the pinhole 160 is configured as an opening portion with respect to a light shielding unit. At this time, the area of the opening of the light shielding unit by the pinhole 160 is set so that at least the area ratio is 50 [%] or less, and desirably the area ratio is 25 [%] or less with respect to the area of the top surface of the photoelectric conversion unit 121.

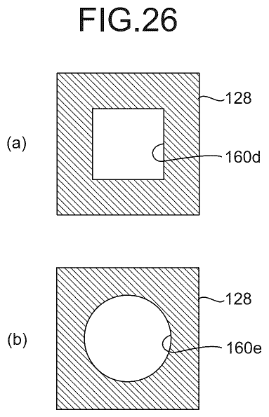

FIG. 26 is a schematic diagram illustrating an example of the pinhole 160 having an area ratio of 25 [%] according to the first embodiment. A section (a) of FIG. 26 illustrates an example of the pinhole 160d having a rectangular (square) shape and an area ratio of 25 [%]. Furthermore, a section (b) of FIG. 26 illustrates an example of the pinhole 160e having a circular shape and an area ratio of 25 [%].

Further, the lower limit of the size of the pinhole 160 is desirably about ½ of a target wavelength λ. For example, in a case where the pixel 100a receives light in the wavelength region of 700 [nm] to 1000 [nm], the lower limit of the size of the pinhole 160 is 350 [nm] that is ½ of the lower limit wavelength λ=700 [nm] of the target wavelength region. In the case of the pinhole 160a having a circular shape, the lower limit of the diameter is 350 [nm]. In the case of the pinhole 160b having a rectangular (square) shape, for example, the lower limit of the side length is 350 [nm].

(4-2. Modification of Light Shielding Film Applicable to First Embodiment)

Next, a modification of the light shielding film 130 applicable to the first embodiment will be described.

It is more desirable that the light shielding film 130 is formed to be a multilayer film having two or more layers, the outermost surface on the photoelectric conversion unit 121 side is provided as the reflection film 127, and the outermost surface on the light incident side is provided as the anti-reflection film 128. The reflection film 127 is provided on the outermost surface on the side of the photoelectric conversion unit 121, thereby making it possible to allow reflected light from the wiring layer 150 to be returned to the photoelectric conversion unit 121 and to contribute to improvement in sensitivity. Furthermore, the anti-reflection film 128 is provided on the outermost surface on the light incident side, thereby making it possible to reduce light reflected by the light shielding film 130 without passing through the pinhole 160, and to suppress a flare or a ghost.

As the reflection film 127, for example, a metal material having high reflectance such as Al, copper (Cu), gold (Au), silver (Ag), or platinum (Pt), or an alloy thereof may be used. Alternatively, a multilayer film designed to have anti-reflection by a laminated structure of dielectric films may be used. These films are formed by using CVD, ALD, sputtering, or the like.

As the anti-reflection film 128, for example, a metal material having low reflectance such as W or Ti, an alloy thereof, a nitride thereof, an oxide thereof, or a carbide thereof may be used. Alternatively, a multilayer film designed to have anti-reflection with a laminated structure of dielectric films may be used. These films are formed by using CVD, ALD, sputtering, or the like. In addition, an organic film containing an absorbent material such as carbon black may be spin-coated on the reflection film 127.

After the multi-layered light shielding film 130 is formed, a resist mask in which a pinhole portion is opened is formed with a lithography process, the pinhole 160 is formed by etching, and a resist and a residue are removed by ashing, chemical cleaning, or the like.

In addition, after the reflection film 127 is formed, a first stage of the pinhole 160 may be formed with the above-described manufacturing method by lithography and etching, and then the anti-reflection film 128 may be formed to form a second stage of the pinhole 160 with an opening size different from that of the first stage. By forming the first and second stages in this manner, the light shielding film thickness at the end portion of the pinhole 160 becomes thin, and deterioration in sensitivity due to a vignetting component can be suppressed. In particular, oblique incidence resistance at the angle-of-view end can be improved.

Alternatively, as another method, the light shielding film thickness of the end portion of the pinhole 160 can be reduced by forming the pinhole portion in a tapered shape with a resist mask and performing etching by controlling a transfer condition such as focusing in a lithography process or performing reflow processing of the resist after development. Similarly, deterioration in sensitivity due to a vignetting component can be suppressed, and particularly, oblique incidence resistance at the angle-of-view end can be improved. The tapering of the resist mask is a method in which processing variations of the opening size increase, but the same can reduce the number of processes.

In addition, in a case where an organic film containing an absorbent material such as carbon black is used as the anti-reflection film 128, the pinhole portion may be formed by lithography transfer and development by mixing a photosensitive agent, and the etching process can be reduced.

(4-3. Modification of Element Separating Unit Applicable to First Embodiment)

Next, a modification of the element separating unit 124a applicable to the first embodiment will be described.

(First Modification of Element Separating Unit)

FIG. 27 is a schematic diagram illustrating a structure example of a pixel 100b applicable to a first modification of the element separating unit of the first embodiment. In FIG. 27, an element separating unit 124b may have a trench structure including the fixed charge film 141 and a gap 134. The trench width at the opening upper end portion of the trench structure is desirably 100 [nm] or less in consideration of a blocking property when the gap 134 is formed. After the trench processing is performed by the above-described method, the fixed charge film 141, for example, Al₂O₃ is formed by ALD, with the size of for example, about 10 to 20 [nm]. The fixed charge film 141 is formed on the side wall of the trench, and the influence of processing damage can be reduced by pinning reinforcement.

Next, a film of Ta₂O₅ is formed by a method with poor coverage such as sputtering to close the opening at the upper portion of the trench, and the gap 134 is formed inside the trench. Thereafter, the insulating film 132, for example, SiO₂ may be formed.

The gap 134 is an air layer having a refractive index n=1, and has a large difference in refractive index from the semiconductor substrate 140 as compared with the insulating film 132, so that light incident on the element separating unit 124b is reflected and returned to the photoelectric conversion unit 121 of the own pixel, thereby contributing to improvement in sensitivity and suppression of crosstalk. Even in a case where closing is insufficient and the element separating unit 124b has a trench structure including the fixed charge film 141, the insulating film 132, and the gap 134, the effect of the refractive index difference due to the gap 134 can be obtained.

(Second Modification of Element Separating Unit)

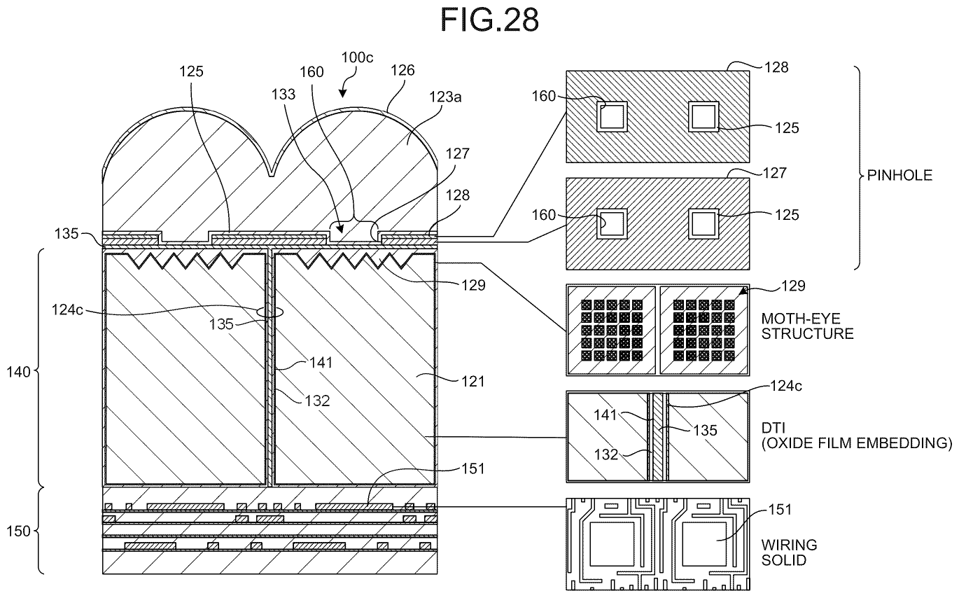

FIG. 28 is a schematic diagram illustrating a structure example of a pixel 100c applicable to a second modification of the element separating unit of the first embodiment. In FIG. 28, in an element separating unit 124c, the fixed charge film 141, the insulating film 132, and an embedded light shielding film 135 may be embedded in a trench. The trench width is desirably 100 [nm] or more in consideration of embeddability of the embedded light shielding film 135.

After the trench processing is performed by the above-described method, the fixed charge film 141 is formed by, for example, ALD with Al₂O₃ of about 10 to 20 [nm], and the same is formed by a method with poor coverage such as sputtering with Ta₂O₅ of about 40 to 80 [nm] so as to obtain an anti-reflection effect. Then, the insulating film 132, for example, SiO₂ is formed to have a thickness of about 30 to 70 [nm] by ALD so as not to close the upper end of the trench.

Next, the embedded light shielding film 135 is embedded with a metal film such as Al or W by a method such as CVD, ALD, or sputtering. A barrier metal having a high melting point material such as Ti, Ta, W, Co, Mo, an alloy thereof, a nitride thereof, an oxide thereof, or a carbide thereof may be provided on the base. By providing the barrier metal, adhesion to the layer in contact with the barrier metal can be enhanced.

When W is used as the embedded light shielding film 135, crosstalk to adjacent pixels can be suppressed, but there is a risk that slight deterioration in sensitivity may occur due to absorption of light by W embedded in the element separating unit 124.

When Al is used as the embedded light shielding film 135, reflectance is higher than that of a metal material, and light reflected by the element separating unit 124 returns to the photoelectric conversion unit 121 of the own pixel, so that improvement in sensitivity can be expected as compared with W. On the other hand, a known method such as high-temperature sputtering or the like can be used for embedding Al in the trench without using a barrier metal, but the process difficulty is high, and there is a possibility that yield is lowered due to defective embedding.

In addition to W and Al, the embedded light shielding film 135 can be formed of Cu, Ag, Au, Pt, Mo, Cr, Ti, Ni, iron (Fe), tellurium (Te), or the like, or an alloy containing these metals. In addition, a plurality of these materials may be laminated to form the embedded light shielding film 135.

(Third Modification of Element Separating Unit)

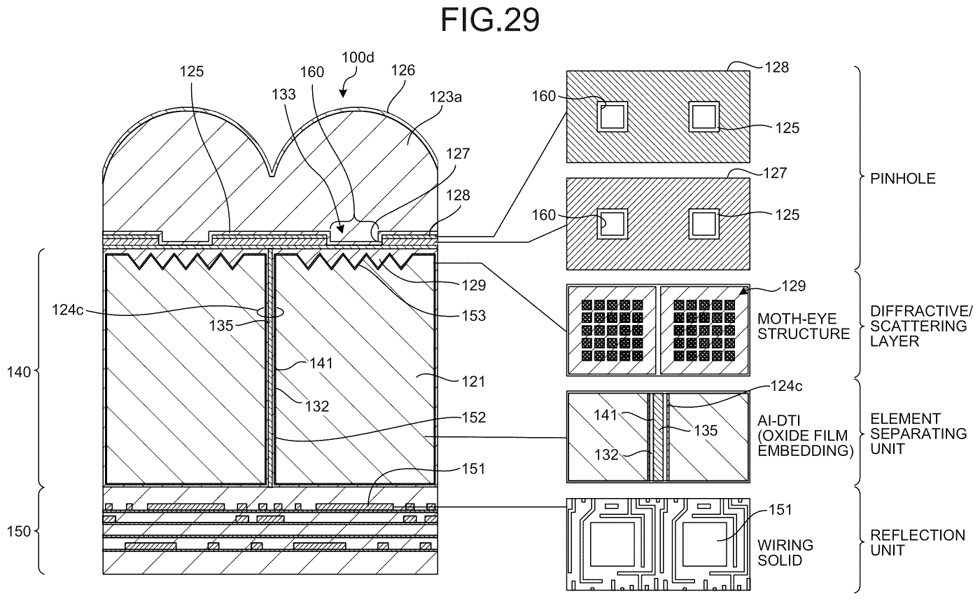

FIG. 29 is a schematic diagram illustrating a structure example of a pixel 100d applicable to a third modification of the element separating unit of the first embodiment. In the pixel 100c described with reference to FIG. 28, the embedded light shielding film 135 on the photoelectric conversion unit 121 may be removed by entire surface polishing by CMP or entire surface etch-back, and the light shielding film 130 may be formed again. By configuring the upper end of the embedded light shielding film 135 to be in contact with the planar light shielding film 130, the crosstalk suppression effect can be enhanced. In this case, a combination is preferable in which the embedded light shielding film 135 is made of W having excellent embedding properties by combining Ti as a barrier metal, and the planar light shielding film 130 is made of Al having high reflectance and difficult to be embedded.

Alternatively, the metal forming the light shielding film 130 can also serve as the embedded light shielding film 135, and the advantage of reducing the number of processes can be obtained. In this case, it is preferable that the reflection film 127 on the lower surface of the light shielding film 130 and the embedded light shielding film 135 of the element separating unit 124 are also made of Al having high reflectance.

In this case, when Al is embedded in the trench by high-temperature sputtering or the like after trench processing, film formation of Al is also performed on the plane portion. The pinhole 160 may be formed by etching the Al serving as the light shielding film 130 on the resist mask. Alternatively, Al may be used as the reflection film 127, and the anti-reflection film 128, for example, W may be formed thereon, and then pinhole processing may be performed.

(4-4. Modification of Reflection Unit on Wiring Layer Side Applicable to First Embodiment)

Next, a modification of the reflection unit 151 applicable to the first embodiment will be described.

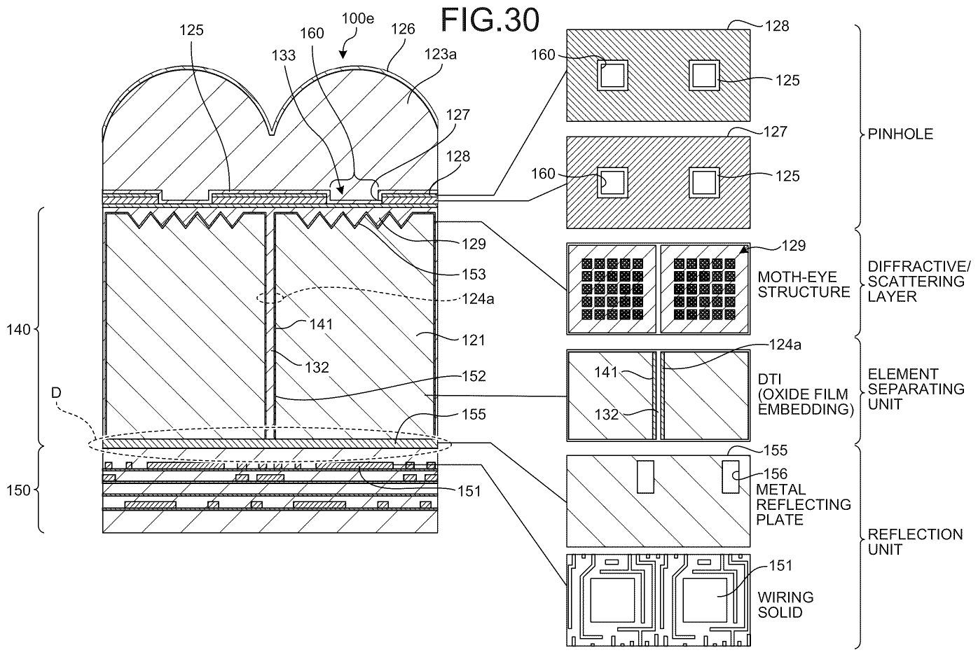

FIG. 30 is a schematic diagram illustrating a structure example of a pixel 100e applicable to a modification of the reflection unit on the wiring layer side according to the first embodiment. The reflection unit 151 may be formed on the surface opposite the light receiving side of the semiconductor substrate 140. The reflection unit 151 may be, for example, a metal material such as Al, Ag, Au, Cu, Pt, Mo, Cr, Ti, Ni, W, or Fe, an alloy material containing these metals, or a metal reflecting plate 155 having a stacked structure. The metal reflecting plate 155 needs to open the periphery of the connection via included in the wiring layer 150. Furthermore, the metal reflecting plate 155 is desirable to be grounded so as not to be destroyed by plasma damage due to accumulated charges during processing.

(Example of Method of Manufacturing Metal Reflecting Plate)

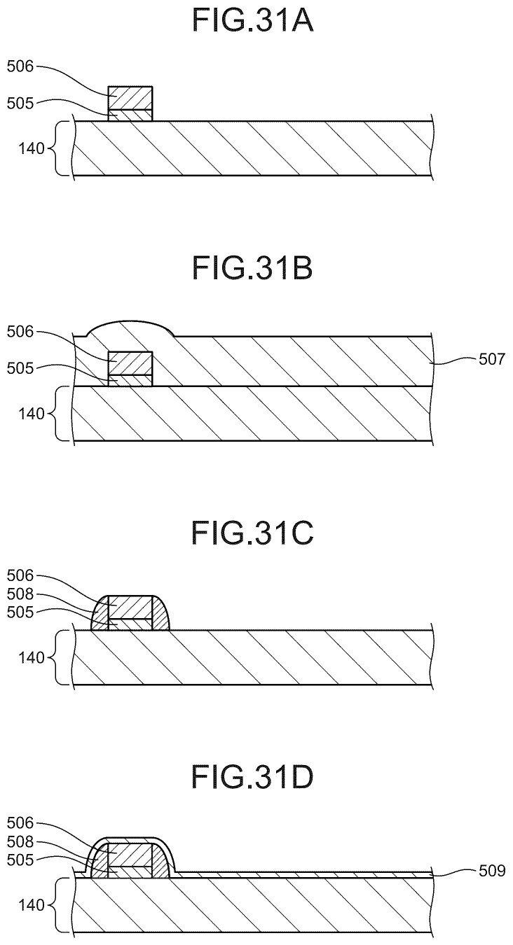

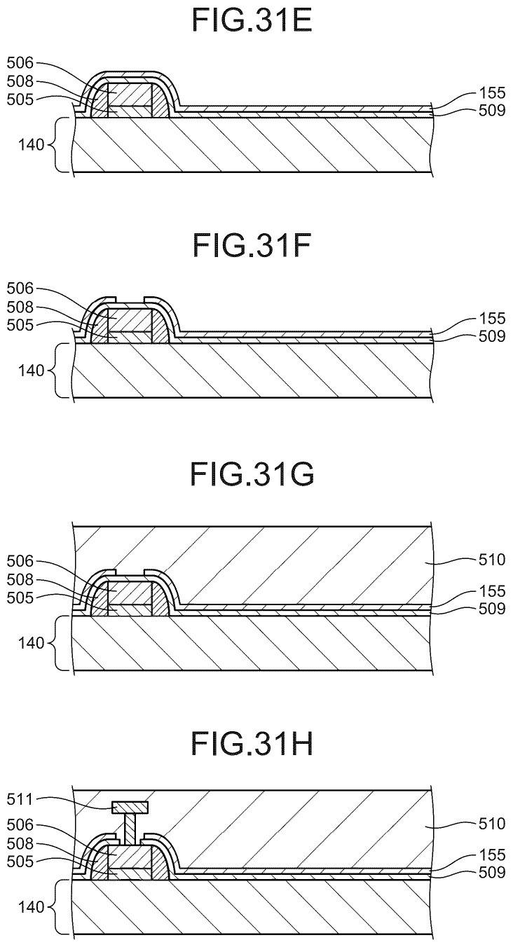

An example of a method of manufacturing the metal reflecting plate 155 applicable to the first embodiment will be described with reference to FIGS. 31A to 31H. First, a p-type well region and an n-type semiconductor region are formed on the semiconductor substrate 140 by ion implantation, a gate insulating film 505 is formed on the surface of the semiconductor substrate 140 by thermal oxidation, polycrystalline silicon is formed, and a resist mask is etched to form a gate 506 (FIG. 31A).

Next, an insulating film 507, for example, SiO₂ is formed by CVD. It is noted that a SiN film serving as an etching stopper may be disposed below SiO₂ (FIG. 31B).

Next, a sidewall insulating film 508 is formed on the gate side surface by anisotropic dry etching (FIG. 31C). Further, an insulating film 509, for example, SiO₂ is formed on the surface of the semiconductor substrate 140 by CVD (FIG. 31D). Next, the metal reflecting plate 155 to be a material of the reflection unit 151 is formed on the front surface side of the semiconductor substrate 140 by CVD or sputtering (FIG. 31E).

Next, the metal reflecting plate 155 is etched on the resist mask to form an opening portion and the like for a connection via near the gate (FIG. 31F). Thus, the reflection unit 151 can be formed on the opposite side of the light receiving surface of the semiconductor substrate 140. Thereafter, an interlayer insulating film 510 is formed (FIG. 31G), and the wiring layer 150 and a subsequent layer such as a connection via 511 are formed (FIG. 31H).

It is noted that the reflection unit 151 is not limited to be formed on the surface portion of the semiconductor substrate 140, and the same may be formed, for example, between a surface opposite the light receiving side of the semiconductor substrate 140 and a wiring layer closest to the surface. Alternatively, it is also possible to form the reflection unit 151 between wiring layers included in the wiring layer 150. In either case, the interlayer insulating film 510 may be formed to have a film thickness smaller than a desired film thickness required for insulation, and the metal reflecting plate 155 may be formed. Thereafter, an opening portion including the connection via 511 may be formed in the resist mask, and the remaining interlayer insulating film 510 may be formed to have a desired film thickness. It is noted that disposing the metal film in the vicinity of the wiring layer 150 causes electromagnetic interaction with a wiring through which a current flows and the connection via 511, therefore, it is necessary to separate the required distance and perform design in consideration of wiring capacitance.

In any of the manufacturing methods, it is desirable that a part of the underlying insulating film 509 is subjected to trench processing by etching using a resist mask before the metal reflecting plate 155 is formed, and is grounded to the lower wiring or the semiconductor substrate 140.

The film thickness of the reflection unit 151 may be set so that infrared light is selectively reflected by a multilayer film 153 formed of insulators having different refractive indices in the reflection unit, and a low bending film and a high bending film may be alternately laminated. The low bending film is preferably, for example, a silicon oxide film. As the high bending film, SiN, titanium oxide (TiO₂), alumina (Al₂O₃), tantalum oxide (Ta₂O₅), α-Si, or the like can be used. In this case, in a case where the reflection unit 151 is formed of the insulating multilayer film 153, there is an advantage that grounding is unnecessary, an influence on wiring capacitance is relatively small, and an opening process for the connection via 511 is unnecessary. It is noted that, in a case where a target wavelength is used differently than expected, the anti-reflection design may deviate and the reflectance may deteriorate.

(4-5. Modification of Optical Waveguide Applicable to First Embodiment)

Next, a modification of the optical waveguide 133 of the first embodiment will be described.

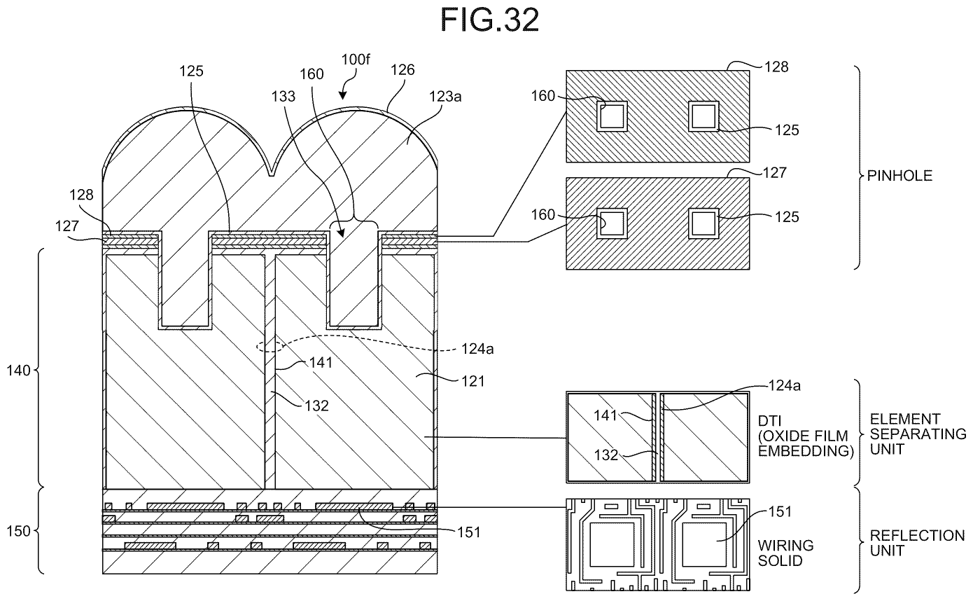

FIG. 32 is a schematic diagram illustrating a structure example of a pixel 100f applicable to a modification of the optical waveguide applicable to the first embodiment. In the optical waveguide 133 provided inside the pinhole 160, it is desirable that the lower surface of the optical waveguide 133 protrudes from the lower surface of the pinhole 160 and extends toward the photoelectric conversion side. For example, as illustrated in FIG. 32, the optical waveguide 133 may be formed deeper than the light receiving surface of the semiconductor substrate 140.

For example, a hard mask process is used at the time of opening the light shielding film 130. Specifically, after the light shielding film 130 is formed, for example, SiN or the like is formed as an inorganic film, and SiN is processed by etching on a resist mask. Even after the light shielding film 130 is etched using the SiN as a mask, the underlying insulating film 132 and the fixed charge film 141 are etched, and the semiconductor substrate 140 is dug by a Bosch process or the like. A resist and a processing residue are removed with a chemical solution. If necessary, a processing damage layer of a substrate formed on the side wall may be removed by wet etching or the like. Alternatively, by forming the dug shape of the optical waveguide 133 with respect to the semiconductor substrate 140 into a tapered shape, it is possible to suppress a reflection phenomenon by a seepage effect of light and to increase a probability of allowing the light to move to the semiconductor substrate 140 side by multiple reflections on an opposing slope even if the light is reflected. The tapered shape may be formed into a quadrangular pyramid by utilizing, for example, wet etching of a Si (111) surface, or may be formed into a tapered shape by enhancing deposition conditions of the Bosch process.

Next, a cladding portion 136 of the optical waveguide is formed. For example, in the first film formation, it is desirable to use a material exemplified as the fixed charge film 141 in order to reinforce pinning, and for example, here, Al₂O₃ is formed by ALD with the size of about 10 to 20 [nm]. Furthermore, in consideration of anti-reflection at the bottom portion of the optical waveguide 133, it is preferable to form films, for example, respectively using Ta₂O₅ with the size of about 50 to 70 [nm], SiO₂ with the size of about 80 to 100 [nm], and SiN with the size of about 110 to 140 [nm] by using CVD, ALD, sputtering, or the like. This description is merely an example, and a combination serving as anti-reflection is not limited to the above description. By providing the optical waveguide 133 in this manner, light can be reliably guided from the pinhole 160 to the photoelectric conversion unit 121.

As another modification, it is also possible to directly form a film of silicon serving as a lens material after the fixed charge film is formed. Alternatively, although pinning cannot be reinforced and there is a concern of deterioration in dark time characteristics, a material of the on-chip lens 123, for example, α-Si may be embedded in the hole portion without the fixed charge film. With this arrangement, seamless light propagation without a difference in refractive index becomes possible.

(4-6. Modification of Diffractive/Scattering Structure Applicable to First Embodiment)

Next, a modification of the diffractive/scattering structure 129 applicable to the first embodiment will be described.

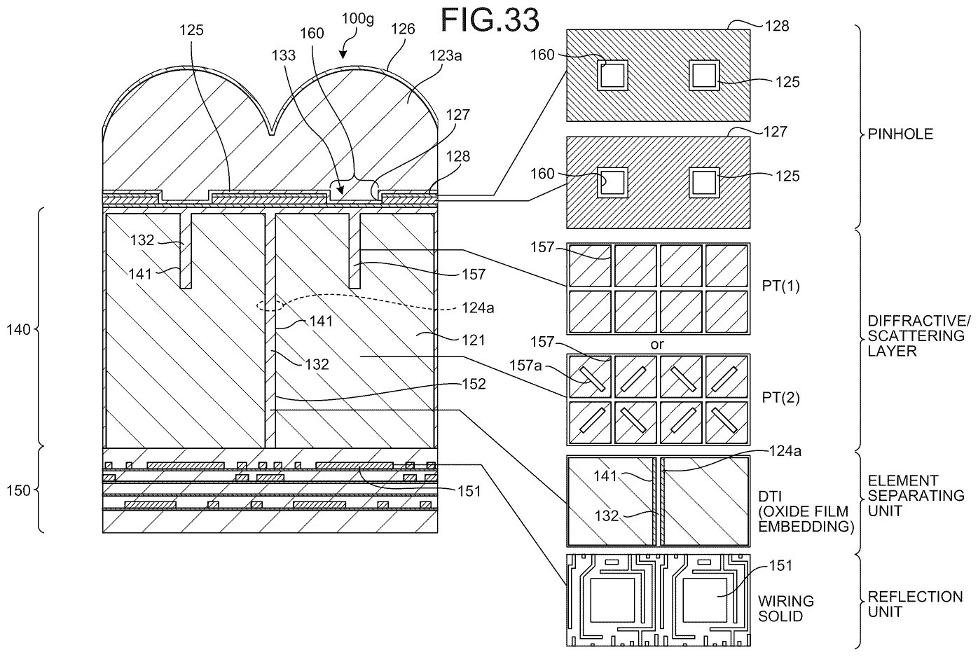

FIG. 33 is a schematic diagram illustrating a structure example of a pixel 100g applicable to a modification of the diffractive/scattering structure of the first embodiment. A light branching unit 157 is formed by forming a trench in the top portion of the photoelectric conversion unit 121 and embedding the fixed charge film 141 and the insulating film 132, for example, SiO₂ by ALD in the trench. Alternatively, the fixed charge film 141 and the gap 134 described in the modification of the element separating unit 124 may be embedded in the trench of the light branching unit 157. The light branching unit 157 may be disposed directly below the pinhole. However, in a case where the angle of the incident light increases at the angle-of-view end, it is desirable to provide the light branching unit 157 at a position where the light condensed by the on-chip lens 123 passes through the pinhole 160 and reaches the top of the photoelectric conversion unit 121. That is, the light branching unit 157 shifts within the angle of view in the same manner as that of pupil correction.

Furthermore, the light branching unit 157 is provided from the top of the photoelectric conversion unit 121 to a relatively shallow position thereof. The depth (length from the top) of the light branching unit 157 is preferably determined in consideration of, for example, the diameter of the pinhole 160, the size of the photoelectric conversion unit 121, the assumed incident angle of the incident light 30, and the like.

The incident light 30 passes through the pinhole 160, is scattered by the light branching unit 157, and changes the optical path thereof. In this manner, the light branching unit 157 functions as a deflection unit configured to deflect light in the oblique direction. In this modification, the diffractive/scattering structure 129 by the moth-eye structure is not provided.

The light scattered by the light branching unit 157 is further reflected by, for example, the side wall of the photoelectric conversion unit 121, the optical path length of the light can be increased, and 0th-order light is reduced, so that improvement of sensitivity can be expected. On the other hand, by providing the light branching unit 157, the ratio of oblique light is increased inside the photoelectric conversion unit 121, and there is a possibility that an influence such as light absorption and crosstalk by the side wall of the photoelectric conversion unit 121 increases.

When viewed from the incident side of the incident light 30, the light branching unit 157 can be provided to cross the pinhole 160 at the angle of 90°, for example, as illustrated as a pinhole pattern PT (1) in the right diagram of FIG. 33. At this time, the crossing angle is not limited to 90°. Furthermore, as illustrated as a pinhole pattern PT (2) in the right diagram of FIG. 33, a light branching unit 157a may be further provided for the crossed light branching unit 157. The light branching unit 157 is provided in this manner, thereby making it possible to increase the ratio of oblique light propagating through the photoelectric conversion unit 121, and to improve sensitivity.

The embedding of the fixed charge film 141 and the insulating film 132 into the trench groove of the light branching unit 157 can be performed simultaneously with the embedding of the element separating unit 124 to reduce the number of processes.

(4-7. Modification of Anti-Reflection Film Applicable to First Embodiment)

Next, a modification of the anti-reflection film applicable to the first embodiment will be described.

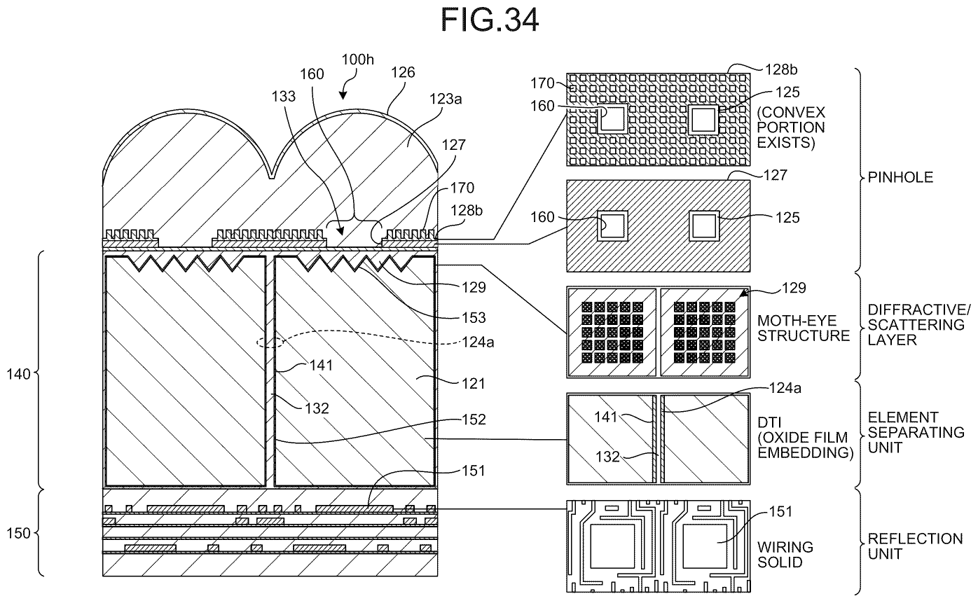

FIG. 34 is a schematic diagram illustrating a structure example of a pixel 100h applicable to a first modification of the anti-reflection film of the first embodiment. FIG. 34 illustrates an example in which a plurality of convex portions 170 are provided on the surface of the light shielding unit on the side of the on-chip lens 123a. More specifically, an anti-reflection film 128b by W provided on the upper surface side of the light shielding unit has a configuration in which the plurality of convex portions 170 are provided on the surface on the side of the on-chip lens 123a. In the manufacturing method, for example, after the hole portion of the pinhole 160 is formed in the light shielding film 130, a resist mask corresponding to the convex portion 170 is formed again in the lithography process, the resist mask is transferred to the light shielding film by etching, and a resist and a residue are removed by wet cleaning. Thereafter, the anti-reflection film 125 and α-Si are formed by CVD or the like, planarized by CMP, and processed into a lens shape by the above-described method.

As described above, the plurality of convex portions 170 are provided on the surface of the light shielding unit on the side of the on-chip lens 123a, thereby making it possible to scatter light emitted to the periphery of the pinhole 160 and to suppress occurrence of a flare and a ghost image. On the other hand, for example, as compared with the configuration of the pixel 100a according to the first embodiment, the number of processes required for manufacturing may increase, which may lead to an increase in cost. It is noted that the plurality of convex portions 170 may be provided periodically or aperiodically.

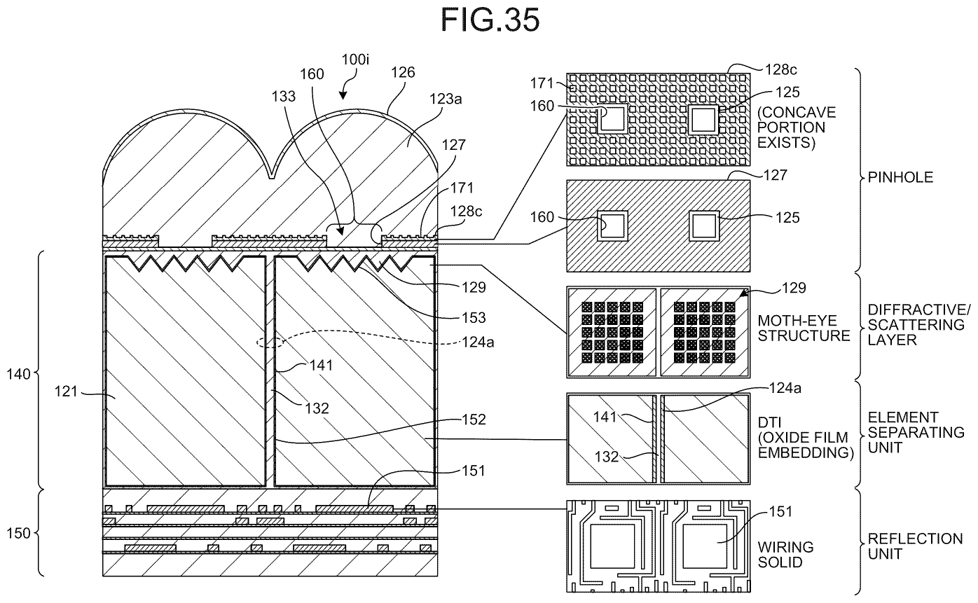

FIG. 35 is a schematic diagram illustrating a structure example of a pixel 100h applicable to a second modification of the anti-reflection film of the first embodiment. FIG. 35 illustrates an example in which a plurality of concave portions 171 are provided on the surface of the light shielding unit on the side of the on-chip lens 123a. More specifically, an anti-reflection film 128c by W provided on the upper surface side of the light shielding unit has a configuration in which the plurality of concave portions 171 are provided on the surface on the side of the on-chip lens 123a. The manufacturing method is the same as that of the convex portion described above, and description thereof is omitted.

As described above, the plurality of concave portions 171 are provided on the surface of the light shielding unit on the side of the on-chip lens 123a, thereby making it possible to scatter light emitted to the periphery of the pinhole 160, and to suppress occurrence of a flare and a ghost image, in the same manner as that of the tenth modification of the first embodiment described above. On the other hand, for example, as compared with the configuration of the pixel 100a according to the first embodiment, the number of processes required for manufacturing may increase, which may lead to an increase in cost. It is noted that the plurality of concave portions 171 may be provided periodically or aperiodically.

(4-8. Modification of On-Chip Lens Applicable to First Embodiment)

Next, a modification of the on-chip lens applicable to the first embodiment will be described.

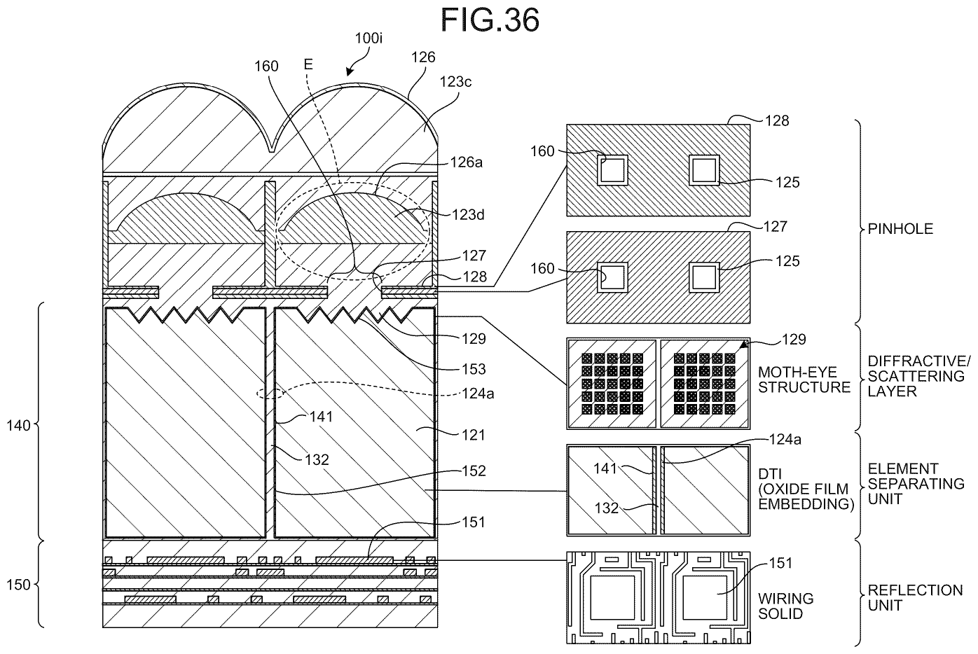

FIG. 36 is a schematic diagram illustrating a structure example of a pixel 100i applicable to a modification of the on-chip lens of the first embodiment. FIG. 29 illustrates an example in which an on-chip lens 123d is added as a second lens between an on-chip lens 123c and the light shielding film 130.

The on-chip lenses 123c and 123d may be made of, for example, α-Si, the periphery of the on-chip lens 123d may be filled with SiO₂, and an anti-reflection film may be provided at each lens interface with SiN of about 100 to 150 [nm].

In the case of the configuration in which lenses are provided in two stages of the on-chip lenses 123c and 123d, it is possible to improve light condensing capability in the pinhole 160 as compared with the case where lenses are provided in one stage. Therefore, as a material of the on-chip lenses 123c and 123d, a material other than α-Si or polycrystalline silicon can be used. Examples of the material include SiN, TiO₂, and Al₂O₃.

In the region where the on-chip lens 123d is provided, a light-shielding wall is provided between the adjacent pixels by a light-shielding material such as metal, for example, W.

As described above, the pixel 100i is configured to be provided with the on-chip lenses 123c and 123d in a double manner, so that the degree of light condensation at the position of the pinhole 160 can be increased, and the diameter of the pinhole 160 can be reduced. Therefore, light can be efficiently confined inside the photoelectric conversion unit 121, and improvement in sensitivity can be expected. On the other hand, since the on-chip lens is formed in a double manner, for example, the number of processes required for manufacturing increases as compared with the configuration of the pixel 100a according to the first embodiment, which may cause an increase in cost. In addition, it is preferable to consider that the height of the pixel increases due to a PAD opening or the like with respect to the configuration in which only one on-chip lens is provided.

(4-9. Modification Including Optical Filter Applicable to First Embodiment)

Next, a modification of the first embodiment including an optical filter will be described.

When light other than light in a desired wavelength region to be sensed becomes noise, it is desirable to include an optical filter, and the case of the organic film has been described in the section (d) of FIG. 4 and the like. In addition, it is possible to perform design so that infrared light is selectively transmitted by a multilayer film of two or more kinds of dielectrics having different refractive indices. For example, a stacked structure of a silicon oxide film and a silicon nitride film or a stacked structure of a silicon oxide film and titanium oxide may be used.

Alternatively, a filter using a surface plasmon phenomenon in which a metal film has an aperture at a period equal to or less than a target wavelength may be provided. Alternatively, a filter using a guided mode resonant (GMR) phenomenon configured by integrating a thin film waveguide and a sub-wavelength periodic structure (grating) may be provided.

Alternatively, in order to implement a desired transmittance spectrum, for example, filters having different mechanisms such as a filter made of an organic material, a surface plasmon filter, and a GMR filter may be provided in combination in the longitudinal direction.

(4-10. Modification Including Scattering/Diffractive Structure on Wiring Layer Side Applicable to First Embodiment)

Next, a modification applicable to the first embodiment and including a scattering/diffractive structure on the wiring layer side will be described.

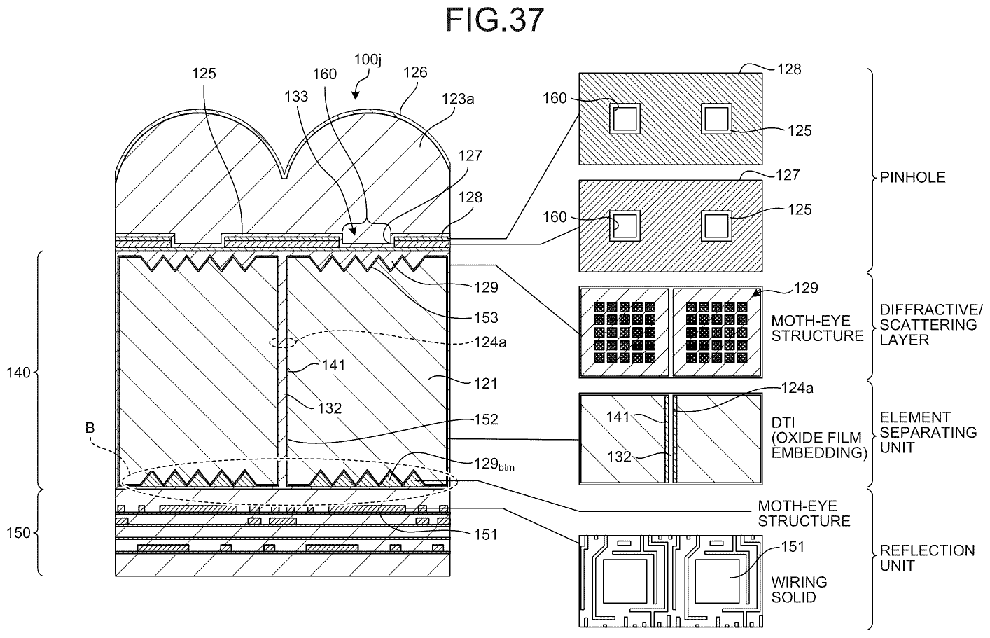

FIG. 37 is a schematic diagram illustrating a structure example of a pixel 100j applicable to a modification in which the scattering/diffractive structure is provided on the wiring layer side of the first embodiment. In the example of FIG. 37, a diffractive/scattering structure 129_{btm} by a moth-eye structure is further provided on the bottom of the photoelectric conversion unit 121, as indicated by a reference sign B. The diffractive/scattering structure 129_{btm} is configured by forming an insulating film such as SiO₂ or SiN on the surface. These multilayer films are preferably designed to reflect light to be transmitted back to the photoelectric conversion unit 121. In addition, the diffractive/scattering structure 129_{btm} has, for example, a moth-eye structure in which quadrangular pyramids are periodically arranged in the same manner as that of the diffractive/scattering structure 129.

In this way, by providing the diffractive/scattering structure 129_{btm} on the bottom of the photoelectric conversion unit 121, for example, it is possible to set an angle with respect to the intra-element reflected light 202 in which the 0th-order light illustrated in FIG. 11A is reflected by the reflection unit 151, and it is possible to further lengthen the optical path length of the intra-element reflected light 202. On the other hand, for example, as compared with the configuration of the pixel 100a according to the first embodiment, the number of processes required for manufacturing may increase, which may lead to an increase in cost.

It is noted that two or more of the first embodiment and each modification of the first embodiment described above can be combined within a range not contradictory to each other.

### 5. Second Embodiment of Present Disclosure

Next, a second embodiment of the present disclosure will be described. The second embodiment is an example in which a structure of a pixel according to the present disclosure is mixed with a pixel for receiving light in a wavelength region of visible light.

It is noted that, with respect to the second embodiment, any one of the pixels 100a to 100j according to the first embodiment and each modification of the first embodiment described above, or a pixel obtained by combining two or more of the structures of the pixels 100a to 100j can be applied within a range not contradictory to each other.

(5-1. Array Example of Pixels Provided with Optical Filter Applicable to Second Embodiment)

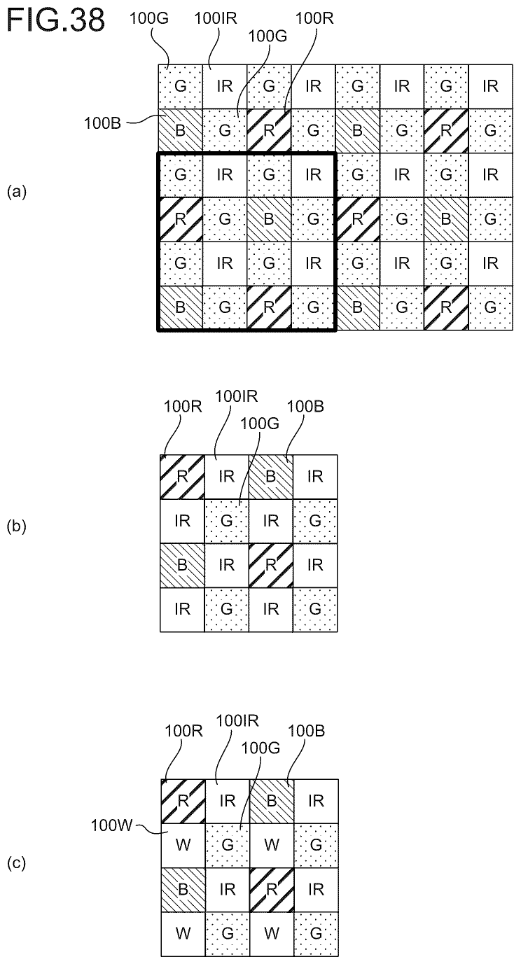

FIG. 38 is a schematic diagram illustrating an example of an array of pixels provided with an optical filter, which is applicable to the second embodiment. As illustrated in a section (a) of FIG. 38, a pixel 100IR (or pixel 100W) may be arranged in a mixed manner with, for example, pixels 100R, 100G, 100B, and the like respectively provided with visible light color filters.

Furthermore, in a case where resolution of a subject by infrared rays is more important and colorization is also required, as illustrated in a section (b) of FIG. 38, an array in which occupancy of the pixel 100IR (or pixel 100W) is increased may be used.

Furthermore, in a case where each of luminance information, color information, and sensing information in a low-illuminance environment is required for one solid-state imaging device, it is conceivable to use a pixel array illustrated in a section (c) of FIG. 38. According to this pixel array, it is possible to acquire luminance information on the pixel 100W, color information on the pixels 100R, 100G, and 100B, and information specialized for sensing information on the pixel 100IR, respectively.

In the array of the sections (a) to (c) of FIG. 38, it is also conceivable that the pixel 100IR (or the pixel 100W) has sensitivity not only to infrared light but also to visible range light. In such a case, it is possible to perform subtraction processing of multiplying the output by a coefficient using the pixels 100R, 100G, and 100B, which are pixels for visible light, and perform signal processing of extracting only a component of a desired wavelength region. Alternatively, in a case where the pixels 100R, 100G, and 100B, which are pixels for visible light, also have sensitivity to infrared light and information on an infrared component is mixed, signal processing of removing the infrared component may be performed on the output of the pixel 100IR.

Further, the combination of the arrays is not limited thereto.

Alternatively, it is possible to acquire a clear and colored image by performing imaging in which infrared light is projected under a low-illuminance environment such as nighttime, performing white balance or linear matrix signal processing using an output of a visible light pixel on a monochrome image of only a luminance signal acquired as an image signal based on the infrared light, and performing coloring by adding signal processing such as machine learning as necessary.

The pixel array is performed in the mixed array as illustrated in the sections (a) to (c) of FIG. 38, thereby making it possible to acquire spectrum information on the subject and then provide sensing information such as a distance of the subject by an IR pixel, unevenness, and the like.

(Example of Electronic Device)

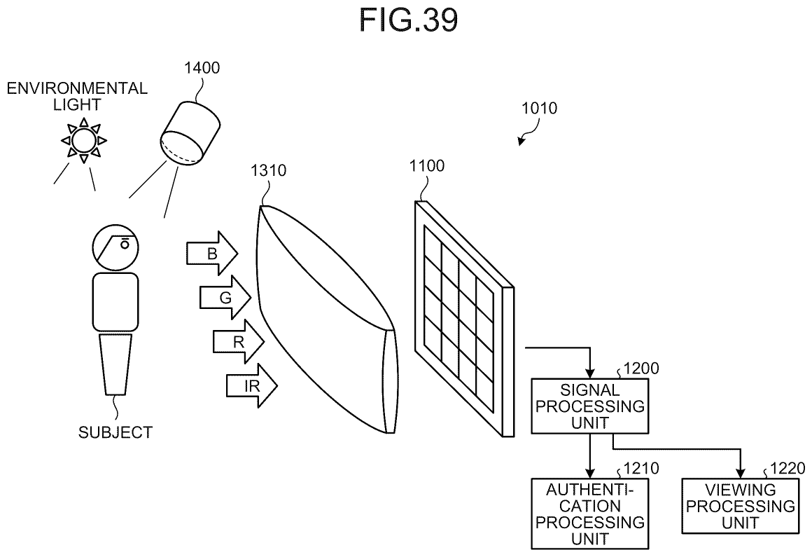

FIG. 39 is a schematic diagram schematically illustrating an electronic device applicable to the second embodiment, the electronic device being configured to acquire spectrum information on a subject and acquire sensing information on the subject by an IR pixel. An image processing system 1010 illustrated in FIG. 39 performs authentication processing and viewing processing based on a signal output from an imaging device 1100.

The image processing system 1010 illustrated in FIG. 39 includes the imaging device 1100 configured to capture an image of a subject, a signal processing unit 1200 configured to process a signal from the imaging device 1100, and an authentication processing unit 1210 configured to perform authentication processing based on an infrared light image. The image processing system 1010 further includes a viewing processing unit 1220 configured to perform viewing processing, an optical unit (imaging lens) 1310 configured to form an image with light from a subject, and a light source unit 1400 configured to irradiate the subject with infrared light. The operation of the entire image processing system 1010 is controlled by a control unit (not illustrated) or the like.

In the configuration of FIG. 39, the signal processing unit 1200 separates a pixel signal from the imaging device 1100 into a pixel signal of a pixel for visible light and a pixel signal of a pixel for infrared light. The viewing processing unit 1220 performs the viewing processing based on RGB information obtained by separating the pixel signal from the imaging device by the signal processing unit 1200.

IR information separated from the pixel signal from the imaging device 1100 by the signal processing unit 1200 is used as an infrared light image. The signal processing unit 1200 detects a phase difference based on the separated IR information and generates information on a distance image. The authentication processing unit 1210 performs the authentication processing using at least one of an image of visible light transmitted from the signal processing unit 1200, luminance information generated by a pixel that receives infrared light, and information on a distance image measured by a pixel that takes infrared light. For example, the authentication processing unit 1210 can perform integrated authentication such as three-dimension (3D) face authentication or iris authentication based on the information on the infrared light image and the distance image.

In the image processing system 1010, the pixel array by the mixed array as illustrated in the sections (a) to (c) of FIG. 38 can be applied to the pixel array in the imaging device 1100.

(Structure Example of IR Pixel)

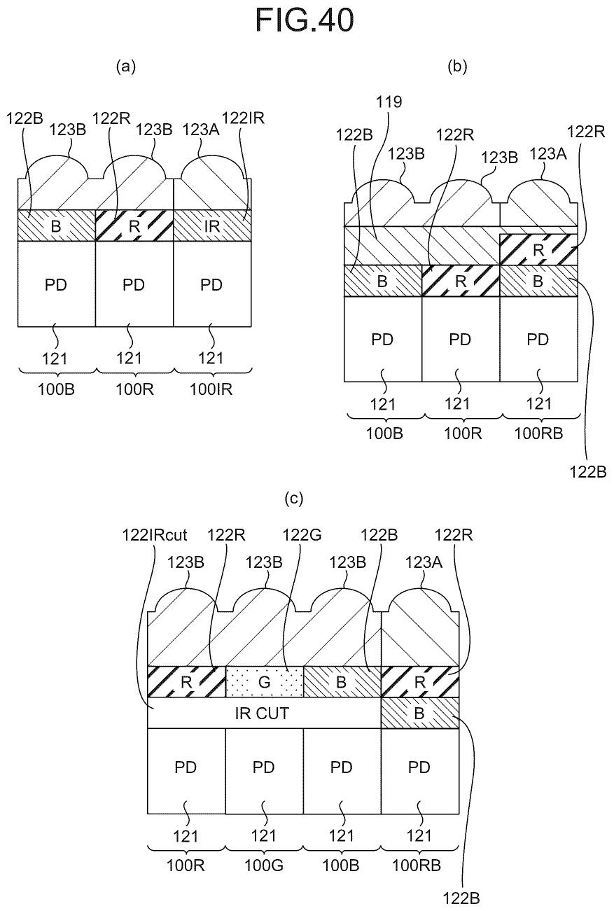

FIG. 40 is a cross-sectional view schematically illustrating a structure example focusing on an optical filter of a pixel, which is applicable to the second embodiment. In FIG. 40, the pinholes 160 and the like are not illustrated in order to avoid complexity.

A section (a) of FIG. 40 illustrates a structure example of pixels 100B, 100G, 100R, and 100IR respectively provided with, as an optical filter, a filter 122B configured to selectively transmit light in a blue wavelength region, a filter 122R configured to selectively transmit light in a red wavelength region, a filter 122G configured to selectively transmit light in a green wavelength region (not illustrated), and a 122IR configured to selectively transmit infrared light. The filter 122IR may be, for example, an organic material containing a pigment or a dye, and for example, an organic material known in Patent Literature 4 may be used.

It is noted that the filter 122IR may further transmit visible light in a predetermined wavelength region (for example, green wavelength region). In this case, an infrared light component can be extracted by signal processing using demosaic processing, matrix processing, or the like based on information of other visible light pixels (pixels 100R, 100G, 100B, and the like) included in the effective pixel region. Therefore, the pixel 100IR may be provided with the filter 122W described above instead of the filter 122IR as an optical filter, and may not include an optical filter.

A section (b) of FIG. 40 illustrates a structure example including a pixel 100B provided with a filter 122B, a pixel 100G provided with a filter 122G (not illustrated), a pixel 100R provided with a filter 122R, and a pixel 100RB provided with the filter 122B and the filter 122R stacked with each other. The filter 122B and the filter 122R are stacked with each other, thereby making it possible to implement a filter configured to absorb most wavelength region components of visible light and to transmit infrared light.

In the structure illustrated in the section (b) of FIG. 40 as well, visible light in a predetermined wavelength region may be further transmitted in the same manner as that of the structure of the section (a) of FIG. 40 described above. The infrared light component can be extracted by signal processing using demosaic processing, matrix processing, or the like based on information on other visible light pixels included in the effective pixel region.

In addition, in the example of the section (b) of FIG. 40, the blue filter 122B and the red filter 122R are stacked with each other, but the present disclosure is not limited to this example. For example, a filter having a complementary color relationship such as cyan and red, magenta and green, or yellow and blue may be combined to absorb visible light.

A section (c) of FIG. 40 is an example in which a filter 122IRcut that cuts (absorbs) infrared light is provided in each of the pixels 100R, 100G, and 100B. In each of the pixels 100R, 100G, and 100B, the filter 122IRcut and filters 122R, 122G, and 122B are stacked with each other. Furthermore, as described above, since the infrared light component can be extracted by signal processing on the pixel signal, the pixel 100RB may be a white pixel provided with no color filter. The present disclosure is not limited thereto, and the pixel 100RB may be provided with an optical filter configured to transmit light of a wavelength region of one color.

It is noted that, in a case where the pixel structure illustrated in FIG. 40 is applied, for example, an infrared light cut filter is not provided in the optical unit 11.

In a case where silicon is used for the on-chip lens 123, light in the visible light region is absorbed, and the sensitivity of the pixels 100R, 100G, and 100B corresponding to the mixed light in the visible light region deteriorates. In a case where the deterioration in sensitivity due to the on-chip lens 123 using silicon is not acceptable, it is desirable to form the on-chip lens 123 by separating the pixels 100R, 100G, and 100B from the IR pixel (pixel 100RB).

In the section (c) of FIG. 40, an on-chip lens 123A corresponding to the pixel 100RB, which is the IR pixel, is formed of silicon. An on-chip lens 123B corresponding to each of the pixels 100R, 100G, and 100B, which are visible light pixels, is formed of a material for visible light, for example, an organic material such as the above-described styrene-based resin or acrylic-based resin, or an inorganic material such as SiN.

It is noted that the visible light pixel and the IR pixel have different required characteristics, and may have different optimal structures. For example, the diffractive/scattering structure 129 is useful for improving the sensitivity for the IR pixel, but the visible light wavelength does not need to be deflected to gain the optical path length because the thickness of the semiconductor substrate 140 is sufficient. Meanwhile, adverse effects such as sensitivity loss of absorption by the element separating unit 124 or crosstalk due to penetration are concerned. In consideration of these situations, it is desirable to generate different structures as necessary.

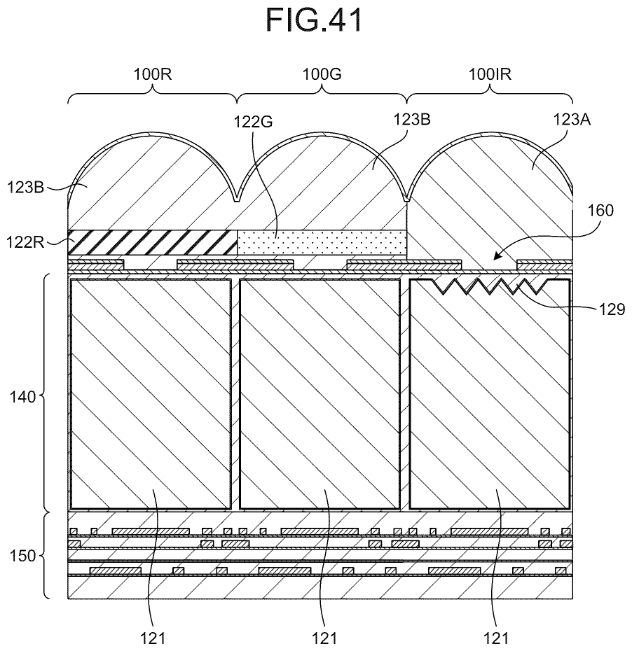

FIG. 41 is a schematic cross-sectional view of a pixel illustrating how to separately form a diffractive/scattering structure according to a pixel, which is applicable to the second embodiment. In this example, the on-chip lens 123A provided in the pixel 100IR, which is the IR pixel, and the on-chip lenses 123B provided in each of the pixels 100R and 100G, which are visible light pixels, are separately formed as described in the section (c) of FIG. 40. Furthermore, the diffractive/scattering structure 129 is also formed separately for the IR pixel and the visible light pixel, and the same is provided in the pixel 100IR and is not provided in each of the pixels 100R and 100B.

For example, the diffractive/scattering structure 129 can be prevented from being formed in the visible light pixel by being covered with a resist mask at the time of processing. Alternatively, the opening size of the pinhole 160 may be made different for each pixel in accordance with wavelength dependency. The anti-reflection film due to an interference effect is desirably multilayered to extend the corresponding wavelength region.

Furthermore, for the on-chip lens 123A, first, a film of a material of the on-chip lens 123A, for example, α-Si is formed and processed into the lens shape by the above-described manufacturing method. Thereafter, etching processing of removing Si on the visible light region is performed in a state of leaving only 123A with a resist mask.

After a resist and a residue are removed by chemical cleaning, exposure and development are performed with, for example, an acrylic resin to which a photosensitive agent is added as a material of the on-chip lens 123B. Thereafter, the resist is reflowed and is cured by performing cross-linking reaction by UV curing, thereby forming the lens shape for visible light. In the lithography process for the on-chip lens 123B, the upper portion of the on-chip lens 123A can be separately formed by selectively removing the resist.

### 6. Third Embodiment of Present Disclosure

Next, a third embodiment of the present disclosure will be described. The third embodiment is an example in which a structure of a pixel according to the present disclosure is applied to a light receiving unit of a distance measuring device configured to perform distance measurement using reflection of light.

It is noted that, with respect to the third embodiment, any one of the pixels 100a to 100j according to the first and second embodiments and each modification of the first embodiment described above, or a pixel obtained by combining two or more of the structures of the pixels 100a to 100j can be applied within a range not contradictory to each other. Hereinafter, for the sake of description, a description will be given on the assumption that the pixel 100a described in the first embodiment is applied to the third embodiment.

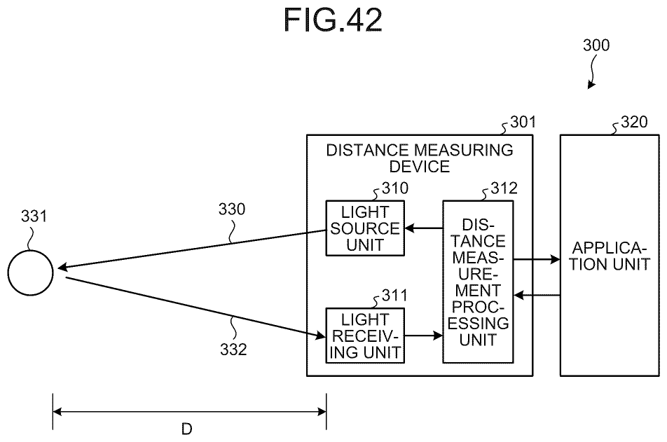

FIG. 42 is a block diagram illustrating a configuration of an example of an electronic device using a distance measuring device applicable to the third embodiment. In FIG. 42, an electronic device 300 includes a distance measuring device 301 and an application unit 320. The application unit 320 is implemented, for example, by a program operating on a central processing unit (CPU), requests the distance measuring device 301 to execute distance measurement, and receives distance information or the like, which is a result of the distance measurement, from the distance measuring device 301.

The distance measuring device 301 includes a light source unit 310, a light receiving unit 311, and a distance measurement processing unit 312. The light source unit 310 includes, for example, a light emitting element configured to emit light having a wavelength in an infrared region, and a drive circuit configured to drive the light emitting element to emit light. For example, a light emitting diode (LED) can be applied as the light emitting element included in the light source unit 310. The present disclosure is not limited thereto, and a vertical cavity surface emitting laser (VCSEL) in which a plurality of light emitting elements are formed in the array shape can also be applied as the light emitting element included in the light source unit 310. Hereinafter, unless otherwise specified, “the light emitting element of the light source unit 310 emits light” will be described as “the light source unit 310 emits light” or the like.

The light receiving unit 311 includes, for example, a light receiving element capable of detecting light having a wavelength in an infrared region, and a signal processing circuit configured to output a pixel signal corresponding to the light detected by the light receiving element. The pixel 100a described in the first embodiment can be applied as the light receiving element included in the light receiving unit 311. Hereinafter, unless otherwise specified, “the light receiving element included in the light receiving unit 311 receives light” will be described as “the light receiving unit 311 receives light” or the like.

The distance measurement processing unit 312 executes, for example, distance measurement processing in the distance measuring device 301 in response to a distance measurement instruction from the application unit 320. For example, the distance measurement processing unit 312 generates a light source control signal for driving the light source unit 310 and supplies the light source control signal to the light source unit 310. Furthermore, the distance measurement processing unit 312 controls light reception by the light receiving unit 311 in synchronization with the light source control signal supplied to the light source unit 310. For example, the distance measurement processing unit 312 generates an exposure control signal for controlling an exposure period in the light receiving unit 311 in synchronization with the light source control signal, and supplies the exposure control signal to the light receiving unit 311. The light receiving unit 311 outputs a valid pixel signal within an exposure period indicated by the exposure control signal.

The distance measurement processing unit 312 calculates distance information based on the pixel signal output from the light receiving unit 311 in response to the light reception and the light source control signal for driving the light source unit 310. Furthermore, the distance measurement processing unit 312 can also generate predetermined image information based on the pixel signal. The distance measurement processing unit 312 transmits, to the application unit 320, the distance information and the image information calculated and generated based on the pixel signal.

In such a configuration, the distance measurement processing unit 312 generates the light source control signal for driving the light source unit 310, for example, in response to an instruction to execute distance measurement from the application unit 320, and supplies the light source control signal to the light source unit 310. At the same time, the distance measurement processing unit 312 controls the light reception by the light receiving unit 311 based on the exposure control signal synchronized with the light source control signal.

In the distance measuring device 301, the light source unit 310 emits light in response to the light source control signal generated by the distance measurement processing unit 312. The light emitted from the light source unit 310 is emitted from the light source unit 310 as emitted light 330. For example, the emitted light 330 is reflected by an object to be measured 331, and the same is received by the light receiving unit 311 as reflected light 332. The light receiving unit 311 supplies a pixel signal corresponding to the reception of the reflected light 332 to the distance measurement processing unit 312.

The distance measurement processing unit 312 measures a distance D to the object to be measured 331 based on a timing at which the light source unit 310 emits light and a timing at which the light receiving unit 311 receives light.

Here, as a distance measuring method using reflected light, a direct time of flight (ToF) method and an indirect ToF method are known. In the direct ToF method, the distance D is measured based on a difference (a time difference) between the timing at which the light source unit 310 emits light and the timing at which the light receiving unit 311 receives light. Furthermore, in the indirect ToF method, the distance D is measured based on a phase difference between a phase of light emitted by the light source unit 310 and a phase of light received by the light receiving unit 311.

The pixel 100a described in the first embodiment can be applied to any one of the light receiving units 311 of the direct ToF and the indirect ToF. As described above, the pixel 100a described in the first embodiment can efficiently confine the incident light 30 inside the photoelectric conversion unit 121, and can achieve both high sensitivity and suppression of a flare caused by the reflected light reflected by the wiring layer 150.

Furthermore, as described with reference to the section (b) in FIG. 10, the external light 33, which is external stray light, can be shielded by providing the pinhole 160. By forming the anti-reflection film 128 on the upper surface side on which the pinhole 160 is formed, it is possible to suppress reflection of light that cannot pass through the pinhole 160 at the bottom of the light intensity distribution. The optical waveguide 133 and the anti-reflection film 125 are provided in the pinhole 160, thereby making it possible to efficiently guide the light condensed by the on-chip lens 123 to the photoelectric conversion unit 121.

Therefore, by applying the pixel 100a described in the first embodiment to the light receiving element in the light receiving unit 311 of the distance measuring device 301 according to the third embodiment, the distance D can be measured with higher accuracy.

It is noted that the effects described in the present specification are merely examples and are not limited, and other effects may be obtained.

It is noted that the present technology can also have the following configurations.
(1) A solid-state imaging device comprising a plurality of pixels, each of the pixels including:
   a substrate having a first surface serving as a light incident surface;
   a photoelectric conversion unit located inside the substrate;
   a light shielding unit provided on a side of the first surface, the light shielding unit having a hole portion configured to allow light to be incident on the photoelectric conversion unit; and
   a first lens made of silicon, the first lens being provided on the light shielding unit and condensing incident light toward the hole portion.
(2) The solid-state imaging device according to the above (1), wherein the first lens is made of amorphous silicon or polycrystalline silicon.
(3) The solid-state imaging device according to the above (1) or (2), wherein at least a part of the hole portion includes a material of the first lens.
(4) The solid-state imaging device according to any one of the above (1) to (3), wherein the hole portion is an optical waveguide.
(5) The solid-state imaging device according to any one of the above (1) to (4),
   wherein an anti-reflection film is provided on at least one of a surface of a light incident side of the first lens and a surface opposite the light incident side.
(6) The solid-state imaging device according to any one of the above (1) to (5),
   wherein a reflection layer is provided on a side of a second surface opposite the first surface of the substrate, and
   wherein the reflection layer is formed of any one of the same material as a wiring included in a wiring layer provided on the side of the second surface, a plurality of laminated films, each of the films having a different refractive index, and a metal film.
(7) The solid-state imaging device according to any one of the above (1) to (6),
   wherein a light diffraction unit is provided on at least one of the first surface of the substrate and a second surface opposite the first surface, the light diffraction unit having an uneven structure in a cross-sectional view.
(8) The solid-state imaging device according to the above (7),
   wherein the uneven structure is formed of one or more quadrangular pyramids provided on the substrate with respect to the one photoelectric conversion unit.
(9) The solid-state imaging device according to any one of the above (1) to (8),
   wherein the first surface of the substrate has a groove portion including an insulating material or an air layer at a position corresponding to the hole portion.
(10) The solid-state imaging device according to the above (9),
   wherein a plurality of the groove portions are provided with respect to the one photoelectric conversion unit.
(11) The solid-state imaging device according to any one of the above (1) to (10),
   wherein a separation unit in contact with the substrate is provided between the two adjacent photoelectric conversion units inside the substrate, the separation unit having a trench structure including an insulating film or the insulating film and an air layer.
(12) The solid-state imaging device according to the above (11),
   wherein, in the separation unit, the trench structure has a metal material embedded therein, and the insulating film is provided between the metal material and the substrate.
(13) The solid-state imaging device according to the above (12),
   wherein the light shielding unit includes a metal film, and
   wherein the metal material included in the separation unit and the metal film included in the light shielding unit are in contact with each other.
(14) The solid-state imaging device according to the above (13),
   wherein the metal material included in the separation unit and a material of the metal film included in the light shielding unit are the same, and the separation unit and the light shielding unit are formed to be integrated.
(15) The solid-state imaging device according to any one of the above (1) to (14),
   wherein the light shielding unit has a plurality of convex portions or concave portions provided on a surface on a side of the first lens.
(16) The solid-state imaging device according to the above (15),
   wherein the light shielding units are provided substantially in parallel in an uneven shape with an insulating film interposed therebetween, the uneven shape being formed by the convex portion or the concave portion on the first surface of the substrate.
(17) The solid-state imaging device according to any one of the above (1) to (16),
   wherein the light shielding unit is formed of a plurality of layers of films, and reflectance on a surface of the light shielding unit, the surface being on a side of the first lens, is lower than reflectance on a surface of the light shielding unit, the surface facing the substrate.
(18) The solid-state imaging device according to any one of the above (1) to (17),
   wherein the light shielding unit has a surface on a side of the first lens, the surface being formed of a film containing carbon.
(19) The solid-state imaging device according to any one of the above (1) to (18),
   wherein at least two pixels of the plurality of pixels respectively have the hole portions, each of the hole portions having a different shape.
(20) The solid-state imaging device according to any one of the above (1) to (19),
   wherein at least two pixels of the plurality of pixels respectively have the hole portions, each of the hole portion having a different position from each other relative to the photoelectric conversion unit.

### REFERENCE SIGNS LIST

10 IMAGING UNIT
20 VERTICAL SCANNING UNIT
21 HORIZONTAL SCANNING/AD CONVERSION UNIT
22 CONTROL UNIT
30 INCIDENT LIGHT
33 EXTERNAL LIGHT
45 OPTICAL MEMBER
100, 100a, 100a_{wc}, 100a_{tc}, 100a_{we}, 100aₜₑ, 100b, 100c, 100d, 100e, 100f, 100g, 100h, 100i, 100j, 100B, 100IR, 100G, 100R, 100RB, 100W PIXEL
101 PIXEL ARRAY UNIT
102 CHARGE HOLDING UNIT
103, 103a, 103b, 103c, 103d MOS TRANSISTOR
121 PHOTOELECTRIC CONVERSION UNIT
123, 123a, 123c, 123d ON-CHIP LENS
124, 124a, 124b, 124c ELEMENT SEPARATING UNIT
125, 126, 128, 128b, 128c ANTI-REFLECTION FILM
127 REFLECTION FILM
129, 129_{btm} DIFFRACTIVE/SCATTERING STRUCTURE
130 LIGHT SHIELDING FILM
132 INSULATING FILM
133 OPTICAL WAVEGUIDE
134 GAP
135 EMBEDDED LIGHT SHIELDING FILM
136 CLADDING PORTION
140 SEMICONDUCTOR SUBSTRATE
141 FIXED CHARGE FILM
142 SUPPORT SUBSTRATE
150 WIRING LAYER
151 REFLECTION UNIT
153 MULTILAYER FILM
155 METAL REFLECTING PLATE
157, 157a LIGHT BRANCHING UNIT
160, 160a, 160b, 160c, 160d, 160e, 160f, 160g, 160sml, 160mid, 160lrg PINHOLE
170 CONVEX PORTION
171 CONCAVE PORTION
202 INTRA-ELEMENT REFLECTED LIGHT
301 DISTANCE MEASURING DEVICE
310 LIGHT SOURCE UNIT
311 LIGHT RECEIVING UNIT
312 DISTANCE MEASUREMENT PROCESSING UNIT

What is claimed is:

1. A solid-state imaging device comprising a plurality of pixels, each of the pixels including:
a substrate having a first surface serving as a light incident surface;
a photoelectric conversion unit located inside the substrate;
a light shielding unit provided on a side of the first surface, the light shielding unit having a hole portion configured to allow light to be incident on the photoelectric conversion unit; and
a first lens made of silicon, the first lens being provided on the light shielding unit and condensing incident light toward the hole portion.

2. The solid-state imaging device according to claim 1,
wherein the first lens is made of amorphous silicon or polycrystalline silicon.

3. The solid-state imaging device according to claim 1,
wherein at least a part of the hole portion includes a material of the first lens.

4. The solid-state imaging device according to claim 1,
wherein the hole portion is an optical waveguide.

5. The solid-state imaging device according to claim 1,
wherein an anti-reflection film is provided on at least one of a surface of a light incident side of the first lens and a surface opposite the light incident side.

6. The solid-state imaging device according to claim 1,
wherein a reflection layer is provided on a side of a second surface opposite the first surface of the substrate, and
wherein the reflection layer is formed of any one of the same material as a wiring included in a wiring layer provided on the side of the second surface, a plurality of laminated films, each of the films having a different refractive index, and a metal film.

7. The solid-state imaging device according to claim 1,
wherein a light diffraction unit is provided on at least one of the first surface of the substrate and a second surface opposite the first surface, the light diffraction unit having an uneven structure in a cross-sectional view.

8. The solid-state imaging device according to claim 7,
wherein the uneven structure is formed of one or more quadrangular pyramids provided on the substrate with respect to the one photoelectric conversion unit.

9. The solid-state imaging device according to claim 1,
wherein the first surface of the substrate has a groove portion including an insulating material or an air layer at a position corresponding to the hole portion.

10. The solid-state imaging device according to claim 9,
wherein a plurality of the groove portions are provided with respect to the one photoelectric conversion unit.

11. The solid-state imaging device according to claim 1,
wherein a separation unit in contact with the substrate is provided between the two adjacent photoelectric conversion units inside the substrate, the separation unit having a trench structure including an insulating film or the insulating film and an air layer.

12. The solid-state imaging device according to claim 11,
wherein, in the separation unit, the trench structure has a metal material embedded therein, and the insulating film is provided between the metal material and the substrate.

13. The solid-state imaging device according to claim 12,
wherein the light shielding unit includes a metal film, and
wherein the metal material included in the separation unit and the metal film included in the light shielding unit are in contact with each other.

14. The solid-state imaging device according to claim 13,
wherein the metal material included in the separation unit and a material of the metal film included in the light shielding unit are the same, and the separation unit and the light shielding unit are formed to be integrated.

15. The solid-state imaging device according to claim 1,
wherein the light shielding unit has a plurality of convex portions or concave portions provided on a surface on a side of the first lens.

16. The solid-state imaging device according to claim 15,
wherein the light shielding units are provided substantially in parallel in an uneven shape with an insulating film interposed therebetween, the uneven shape being formed by the convex portion or the concave portion on the first surface of the substrate.

17. The solid-state imaging device according to claim 1,
wherein the light shielding unit is formed of a plurality of layers of films, and reflectance on a surface of the light shielding unit, the surface being on a side of the first lens, is lower than reflectance on a surface of the light shielding unit, the surface facing the substrate.

18. The solid-state imaging device according to claim 1,
wherein a surface of the light shielding unit on a side of the first lens is formed of a film containing carbon.

19. The solid-state imaging device according to claim 1,
wherein at least two pixels of the plurality of pixels respectively have the hole portions having different shapes from each other.

20. The solid-state imaging device according to claim 1,
wherein at least two pixels of the plurality of pixels respectively have the hole portions having different positions from each other relative to the photoelectric conversion unit.
